(19) United States
(12) Patent Application Publication
(10) Pub. No.: US 2016/0139222 A1
(43) Pub. Date: May 19, 2016

(54) METHODS FOR SPATIAL AND SPECTRAL SELECTIVITY IN MAGNETIC RESONANCE IMAGING AND SPECTROSCOPY

(71) Applicant: YEDA RESEARCH AND DEVELOPMENT CO. LTD., Rehovot (IL)

(72) Inventors: Lucio FRYDMAN, Rehovot (IL); Jean-Nicolas DUMEZ, Rehovot (IL)

(21) Appl. No.: 14/899,173

(22) PCT Filed: Jun. 18, 2014
(86) PCT No.: PCT/IL2014/050552

§ 371 Date: Dec. 17, 2015

Related U.S. Application Data
(60) Provisional application No. 61/836,679, filed on Jun. 19, 2013.

(51) Int. Cl. G01R 33/46; G01R 33/565; G01R 33/483

(52) U.S. Cl. CPC G01R 33/4633; G01R 33/483; G01R 33/56563; G01R 33/56527

(57) ABSTRACT

The present invention provides magnetic resonance multidimensional selectivity based on spatiotemporal encoding (SPEN). In particular, multidimensional selectivity is achieved by the concurrent application of frequency-swept irradiation and magnetic field gradients for the sequential manipulation of spins in space in one dimension or more. Simultaneous spatial and spectral selectivity is disclosed.

### FIELD OF THE INVENTION

The present invention is directed to a method of producing spatial and/or spectral selectivity in nuclear magnetic resonance (NMR) or magnetic resonance imaging (MRI).

### BACKGROUND OF THE INVENTION

Selective radiofrequency (RF) pulses play numerous roles in nuclear magnetic resonance (NMR). In spectroscopy they help simplify the information and afford increased sensitivity. In magnetic resonance imaging (MRI) they are widely used to limit the extent of the spatial region from which the observed NMR signals originate. To perform such task, selective RF pulses are applied in the presence of magnetic field gradients. Each pulse selectively addresses a portion of the sample, leading to slice-, line- or cube-shaped spatial excitations. In many instances, however, more complex 2D or 3D regions of interest (ROIs) are sought. Applications that require 4D selectivity, including addition of a spectral dimension to the three spatial dimensions, can also be envisioned.

Magnetic resonance studies necessitating said complex 2D, 3D or 4D selectivity may be aimed at targeting the shape of a particular organ, exciting selected chemical components with a predefined spatial location within the sample, or endowing complex geometries with pre-set excitation phases that compensate for magnetic field inhomogeneities. Such multidimensional spatial or spectral-spatial selectivity often requires more sophisticated strategies than what can be achieved using simple 1D frequency-selective pulses.

Pulses that are simultaneously spatially and spectrally selective (Meyer et al., Magn. Reson. Med. 15(1990) 287-304), termed SPSP pulses, are often used to avoid chemical shift artifacts by selectively exciting the water resonance in multi-slice 2D imaging studies of fat-containing tissues like brain, liver or breast. Water selectivity also plays an integral component of musculoskeletal studies. In this respect, SPSP approaches have proven more robust than alternative fat saturation techniques (Zur, Magn. Reson. Med. 43 (2000) 410-420). More recently, 2D spectral-spatial pulses have also been exploited for fast spectroscopic imaging of hyperpolarized metabolites (Lau et al., NMR Biomed. 24 (2011) 988-996).

An essential component in the design of frequency-selective pulses in one or more dimensions is the Fourier relationship that, in the limit of small excitation angles, relates a time-dependent B₁ field with the spectral distribution excited as a function of frequency. Walks in reciprocal space enable an extension of classic RF selectivity concepts from one to multiple dimensions. These “excitation k-spaces” provide a unified description relating the shape of the RF waveform as a function of time, with the properties that can be excited from the spins along n spatial dimensions. Fourier-based k-space concepts are also used for the contemporary explanation of many MRI experiments. Walks through k-space, for instance, underlie the operation of echo-planar imaging (EPI) approaches capable of delivering multidimensional spatial profiles in a single-scan.

Although a majority of single-scan MRI experiments exploit such k-space concepts to define the features that characterize the image being sought, a number of alternatives to EPI exist in ultrafast multidimensional MRI (Hennig et al., Magma 1 (1993); Lowe et al., J. Magn. Reson. B 101 (1993) 106-109; Chamberlain et al., Magn. Reson. Med. 58 (2007) 794-799; Shrot et al., J. Magn. Reson. 172 (2005) 179-190; Tal et al., J. Magn. Reson. 182 (2006) 179-194; and Meyerand et al., Magn. Reson. Med. 34 (1995) 618-622). Owing to their ability to probe the spin response throughout a multidimensional space in a single scan, these alternatives might also constitute a basis for the design of multidimensional excitation pulses. One such non-EPI scanning method, known as spatiotemporal encoding (SPEN), relies on measuring the NMR signal in “direct” rather than in reciprocal space. SPEN operates by generating a spin response that at any given instant throughout the signal acquisition carries only contributions from a well-defined and localized region of the sample. This approach has been shown to benefit from robustness against the effect of undesirable frequency offsets which arise, for example, from chemical shifts or magnetic susceptibility differences (Ben-Eliezer et al., Magn. Reson. Imaging 28 (2010) 77-86).

SPEN utilizes frequency-swept pulses and, in particular, linearly-swept “chirp” pulses that are applied in the presence of magnetic field gradients to afford the precession of spins having different resonance offsets for effectively different time periods (US 2010/0315082). This process can be exploited to collect arbitrarily high multidimensional images, spectra or spectroscopic images within a single scan (Tal et al., Prog. Nucl. Magn. Reson. Spectrosc. 57 (2010) 241-292). In 2D magnetic resonance spectroscopy, SPEN provides a general approach, for which no other “ultrafast” alternatives exist.

WO 2004/011899 and WO 2005/062753 to one of the inventors of the present invention disclose a method and apparatus for treating a sample to acquire multidimensional spectra within a single scan that partitions a sample into a set of independent subensembles endowed with different resonance frequencies. A polychromatic irradiation of the sample is implemented whereby the various subensembles are selectively manipulated by a time-incremented series of excitation or refocusing sequences. Thereafter, a homogeneous sequence capable of generating an observable spectral signal from each of the subensembles is applied with simultaneous monitoring of the observable signals arising from the various subensembles in a resolved fashion. The observable signals acquired in this manner are processed into a complete multidimensional spectral data set.

WO 2007/078821 to one of the inventors of the present invention discloses a method and apparatus for treating a sample for acquiring high-definition magnetic resonance images or high resolution nuclear magnetic resonance spectra even in the presence of magnetic field distortions within one or multiple scans.

There remains an unmet need for multidimensional excitation pulses that provide improved spatial and/or spectral selectivity for magnetic resonance imaging and spectroscopy applications with high robustness against magnetic field inhomogeneities and spectral heterogeneities.

### SUMMARY OF THE INVENTION

The present invention provides a method of producing multidimensional selectivity in magnetic resonance imaging and spectroscopy. The method comprises the concurrent application of frequency-swept irradiation pulses and magnetic field gradients for the sequential excitation of spins in at least one dimension, followed by an optional additional irradiation in the presence or absence of magnetic field gradients to remove undesired phase or aliasing imparted to the spins during excitation, or an additional gradient pulse for discriminating a desired spectral component. These selective pulses are then followed by the acquisition of a signal in one or multiple scans, leading to magnetic resonance image of a selected region of interest or magnetic resonance spectra of a component of interest.

The present invention is based in part on the unexpected finding that spatiotemporal-encoding concepts can be used to design multidimensional pulses having concurrent selectivity in two dimensions or more. The operation of the multidimensional pulses of the present invention is distinct from that of k-space-based pulses and affords a high robustness against field inhomogeneities and/or chemical shift offsets. Surprisingly, simultaneous spatial and spectral selectivity can be obtained without using fast oscillating gradients. The method of the present invention can be implemented in many mainstream applications of contemporary magnetic resonance imaging and spectroscopy.

According to a first aspect, the present invention provides a method for producing multidimensional selectivity in magnetic resonance imaging or spectroscopy, the method comprising the steps of: (a) applying a magnetic field gradient being configured to partition a sample into a set of subensembles endowed with different resonance frequencies while concurrently applying a frequency-swept irradiation to sequentially manipulate said subensembles in at least one dimension; (b) optionally applying at least one of an irradiation, a magnetic field gradient, or a combination thereof, being configured to remove undesired phase or aliasing imparted to the subensembles during step (a) or to further manipulate a desired subensemble; and (c) acquiring a signal arising from said subensembles, thereby providing magnetic resonance imaging or spectroscopy with multidimensional selectivity.

In one embodiment, the method provides multidimensional selectivity in multiple dimensions, wherein the multiple dimensions can be multiple spatial dimensions, multiple spatial and spectral dimensions, multiple spatial and displacement-based dimensions, multiple spatial and relaxation-based dimensions, multiple spectral dimensions, and any combination thereof. Each possibility represents a separate embodiment of the present invention. In some embodiments, the method of the present invention provides selectivity in one or several spatial dimensions. In other embodiments, the method of the present invention provides two-dimensional spatial selectivity. In further embodiments, the method of the present invention provides two-dimensional spatial-spectral selectivity. In yet further embodiments, the method of the present invention provides a three-dimensional spatial-spatial-spectral selectivity. In still further embodiments, the method of the present invention provides a three-dimensional spatial-spatial-spatial selectivity. In additional embodiments, the method of the present invention provides a four-dimensional spatial-spatial-spatial-spectral selectivity.

It will be appreciated by one of skill in the art that in order to impart spatial selectivity in more than one dimension, the concurrent application of at least two magnetic field gradients and a frequency-swept irradiation is required.

In some embodiments, the frequency-swept irradiation is a substantially linearly frequency-swept irradiation.

In other embodiments, the frequency-swept irradiation is applied in a continuous manner

In alternative embodiments, the frequency-swept irradiation is applied in a discretized manner

In particular embodiments, the discretized frequency-swept irradiation comprises a plurality of irradiation sub-pulses. It will be appreciated by one of skill in the art that in order to obtain the sequential manipulation of subensembles in at least one dimension, the plurality of sub-pulses are interleaved with a plurality of magnetic field gradients.

In additional embodiments, the frequency-swept irradiation is performed using parallel transmit coils.

In certain embodiments, the step of applying a magnetic field gradient being configured to partition a sample into a set of subensembles endowed with different resonance frequencies while concurrently applying a frequency-swept irradiation to sequentially manipulate said subensembles in at least one dimension is performed in a single scan.

In some embodiments, step (a) includes applying a magnetic field gradient being configured to partition a sample into a set of subensembles endowed with different resonance frequencies while concurrently applying a frequency-swept irradiation to sequentially manipulate said subensembles along a predetermined multidimensional trajectory. In other embodiments, step (a) includes applying a magnetic field gradient being configured to partition a sample into a set of subensembles endowed with different resonance frequencies while concurrently applying a frequency-swept irradiation to sequentially manipulate said subensembles along a predetermined two-dimensional trajectory.

In further embodiments, the step of applying a magnetic field gradient being configured to partition a sample into a set of subensembles endowed with different resonance frequencies while concurrently applying a frequency-swept irradiation further comprises concurrently applying at least one other magnetic field gradient to sequentially manipulate said subensembles along a predetermined multidimensional trajectory. In one embodiment, the present invention provides the use of two orthogonal magnetic field gradients for sequentially manipulating said subensembles along a predetermined two-dimensional trajectory.

In particular embodiments, the two-dimensional trajectory is selected from a Cartesian trajectory, a spiral trajectory and a radial trajectory. Each possibility represents a separate embodiment of the present invention.

In various embodiments, the step of applying a magnetic field gradient being configured to partition a sample into a set of subensembles endowed with different resonance frequencies while concurrently applying a frequency-swept irradiation to sequentially manipulate said subensembles in at least one dimension further comprises concurrently applying at least one other magnetic field gradient being configured to impart spatial selectivity within said subensembles using a predetermined k-space trajectory. In further embodiments, application of a magnetic field gradient being configured to partition a sample into a set of subensembles endowed with different resonance frequencies concurrently with the application of a frequency-swept irradiation, sequentially manipulates said subensembles along a first dimension and application of at least one other magnetic field gradient imparts spatial selectivity within said subensembles, using a predetermined k-space trajectory, along a second dimension. In some embodiments, said first and said second dimensions are orthogonal. In further embodiments, application of a frequency-swept irradiation and application of at least one other magnetic field gradient being configured to impart spatial selectivity within said subensembles using a predetermined k-space trajectory are operated in a hybrid direct and reciprocal space.

In some embodiments, step (a) includes applying a magnetic field gradient being configured to partition a sample into a set of subensembles endowed with different resonance frequencies while concurrently applying a frequency-swept irradiation two-dimensional pulse to sequentially manipulate said subensembles along a predetermined multidimensional trajectory. In other embodiments, step (a) includes applying a magnetic field gradient being configured to partition a sample into a set of subensembles endowed with different resonance frequencies while concurrently applying a frequency-swept irradiation two-dimensional pulse to sequentially manipulate said subensembles along a predetermined two-dimensional trajectory. In certain embodiments said frequency-swept irradiation two-dimensional pulse operates entirely in a direct excitation space. In further embodiments, said two-dimensional pulse is designed by defining the desired trajectory in k-space.

In several embodiments, the removal of undesired phase or aliasing imparted to the subensembles during step (a) or the further manipulation of a desired subensemble comprises applying at least one frequency-swept irradiation in the presence or absence of a magnetic field gradient. In additional embodiments, the removal of undesired phase or aliasing imparted to the subensembles during step (a) or the further manipulation of a desired subensemble comprises applying a crusher magnetic field gradient, a refocusing magnetic field gradient, or a combination thereof as is known in the art. Each possibility represents a separate embodiment of the present invention.

According to certain embodiments, the frequency-swept irradiation induces at least one of excitation, crushing, inversion, refocusing and storage of the subensembles. Each possibility represents a separate embodiment of the present invention.

In some embodiments, the step of acquiring a signal arising from said subensembles comprises the use of at least one of gradient echo, spin echo, fast low angle shot (FLASH), fast spin echo (FSE), and echo planar imaging (EPI). Each possibility represents a separate embodiment of the present invention.

In other embodiments, the step of acquiring a signal arising from said subensembles comprises the use of a time-dependent magnetic field gradient being configured to unravel the partition of the sample into a set of subensembles imparted during step (a).

In further embodiments, the step of acquiring a signal arising from said subensembles is performed in a single scan.

Encompassed within the scope of the present invention is the use of the method disclosed herein for multidimensional magnetic resonance imaging of objects being characterized by complex architectures. Further encompassed by the present invention is the multidimensional magnetic resonance imaging of a region of interest within an object, wherein said region of interest is characterized by complex architectures. It will be appreciated by those of skill in the art that in order to obtain multidimensional imaging of objects or regions of interest within an object being characterized by complex architectures, the method of the present invention may further comprise the application of refocusing magnetic field gradients, crusher magnetic field gradients, or a combination thereof being configured to selectively select or suppress signal from an arbitrarily shaped region.

According to some embodiments, the method of the present invention can be used for localized magnetic resonance spectroscopy in a predetermined region of interest within an object.

It will be appreciated by one of skill in the art that the method of the present invention further provides the spatial compensation for magnetic field inhomogeneities. Accordingly, the present invention provides a method for producing multidimensional selectivity in magnetic resonance imaging or spectroscopy even in the presence of magnetic field distortions.

In additional embodiments, the method of the present invention further comprises the step of processing the acquired signal by using at least one of Fourier transformation, zero-filling, weighting, echo alignment procedures, magnitude calculations, resampling, algebraic reconstruction, and combinations thereof. Each possibility represents a separate embodiment of the present invention.

The present invention further provides a system for magnetic resonance imaging or spectroscopy comprising means for performing the method disclosed herein. In particular embodiments, said means for performing the method disclosed herein comprise at least one of a radiofrequency transmitter suitable for applying a frequency-swept irradiation, a magnetic field gradient suitable for partitioning a sample into a set of subensembles endowed with different resonance frequencies, and a collecting unit suitable for acquiring a magnetic resonance signal.

Further embodiments and the full scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1: One-dimensional excitation in direct space using a linearly frequency-swept pulse. Columns from left to right: continuous uniform chirp pulse; continuous shaped chirp pulse; discrete uniform chirp pulse; and discrete shaped chirp pulse. Rows from top to bottom: RF amplitude; RF phase; gradient amplitude; and magnitudes of the transverse magnetization at the end of the pulse, calculated using Bloch simulations. The region of interest of length ROI is indicated by a double arrow.

FIG. 2A: Bloch-simulations of the transverse magnetizations excited by a chirp pulse. Rows from top to bottom: pulse sequences; magnitude of the transverse magnetization; and phase of the transverse magnetization;

FIG. 2B: Bloch-simulations of the transverse magnetizations excited by the combination of excitation and refocusing chirp pulses. Rows from top to bottom:

pulse sequences; magnitude of the transverse magnetization; and phase of the transverse magnetization.

FIG. 3A: Strategy to separate the excitation center- and side-bands arising upon using discrete excitation and continuous refocusing chirp pulses, illustrated using Bloch simulations—pulse sequence;

FIG. 3B: an illustration of the ROI being sought;

FIG. 3C: continuous excitation and continuous refocusing chirp pulses;

FIG. 3D: discrete excitation chirp pulse and continuous refocusing chirp pulse for three overlapping sidebands.

FIG. 3E: discrete excitation chirp pulse and continuous refocusing chirp pulse illustrating the unfolding of the ROI by filtration.

FIG. 4A: Trajectory in excitation space for a hybrid 2D pulse, where spins are excited sequentially along the “slow” dimension (y), while k-space is used along the “fast” dimension (kₓ);

FIG. 4B: RF and gradient waveform details for a hybrid y/kₓ 2D excitation pulse with Nₑ=25 subpulses. A thin line shows the original continuous modulation of φ_{exc}, sampled with Nₑ discrete steps.

FIG. 5A: Magnetization excited by a hybrid 2D pulse, illustrated with Bloch simulations—the magnitude and real part of the transverse magnetization for a hybrid 2D pulse with N=150 subpulses that sweeps over a region of interest of length ROI_{y} with a time-bandwidth product Q=100.

FIG. 5B: The magnitude and real part of the transverse magnetization of the same hybrid 2D pulse as in FIG. 5A followed by a refocusing chirp pulse that sweeps over the same ROI_{y} in half the duration and with the same gradient amplitude. The two parallel lines of excited magnetization correspond to non-ideal transition regions of the refocusing pulse, and their contribution to the signal is suppressed with crusher gradients.

FIG. 6A: Magnetization excited by a purely SPEN 2D pulse using a blipped Cartesian (left) or a spiral (right) trajectory, illustrated with Bloch simulations—the trajectory followed during excitation in a fully direct space; FIG. 6B: the magnitude of the transverse magnetization excited by the pulse;

FIG. 6C: the real part of the transverse magnetization excited by the pulse. An additional gradient lobe is used to remove the linear phase;

FIG. 6D: the phase profile of the transverse magnetization for a slice x=0; and

FIG. 6E: the phase profile of the transverse magnetization for a slice y=0. The pulses have a time-bandwidth product Q=40 and Nₑ=80, where Nₑ is the number of lines for the blipped Cartesian and the number of turns for the spiral trajectory.

FIG. 7A: Time evolution of excited transverse magnetizations during: a Fourier k-space 2D pulse;

FIG. 7B: a hybrid kₓ/y space 2D pulse; and

FIG. 7C: a purely SPEN 2D spiral pulse, illustrated using Bloch simulations. The three pulses excite a rectangular ROI. The magnitudes of the transverse magnetizations are shown for t=Tₑ/3, 2Tₑ/3 and Tₑ, where Tₑ is the total duration of the pulse. FIG. 8A: Hybrid 2D pulse sequence, with RO, SPEN and SS denoting orthogonal gradients applied along the readout (“x”), SPEN (“y”) and slice-select (“z”) directions, respectively;

FIG. 8B: Single-scan 2D SPEN images obtained after applying hybrid 2D pulses of FIG. 8A that excite rectangular ROI; FIG. 8C: Single-scan 2D SPEN images obtained after applying hybrid 2D pulses of FIG. 8A that excite star-shaped ROI.

FIG. 9A: Common pulse sequence;

FIG. 9B, FIG. 9C: Conventional 2D spin-echo images obtained after a discretized 1D excitation chirp pulse, followed by a continuous refocusing chirp pulse (a common pulse sequence of FIG. 9A);

FIG. 9D, FIG. 9E: Conventional 2D spin-echo images obtained after hybrid 2D excitation pulse that were followed by a continuous refocusing chirp pulse (a common pulse sequence of FIG. 9A).

FIG. 10A: Conventional 2D spin-echo images obtained on a phantom containing five small tubes within a larger tube, using a non-selective pulse;

FIG. 10B: a triangle-sculpting 2D pulse based on a Fourier k-space design; and

FIG. 10C: a triangle-sculpting obtained using the pulse scheme shown in FIG. 8A, combining a hybrid 2D SPEN pulse and a refocusing 180° chirp pulse.

FIG. 11A: Conventional 2D spin-echo images obtained after a Fourier 2D pulse in the presence of small (˜20 Hz) field inhomogeneities. The pulse sequence is shown in FIG. 8A;

FIG. 11B: Conventional 2D spin-echo images obtained after the combination of a hybrid 2D pulse and a refocusing chirp pulse in the presence of small (˜20 Hz) field inhomogeneities. The pulse sequence is shown in FIG. 8A;

FIG. 11C: Conventional 2D spin-echo images obtained after a Fourier 2D pulse in the presence of large (˜200 Hz) field inhomogeneities. The pulse sequence is shown in FIG. 8A;

FIG. 11D: Conventional 2D spin-echo images obtained after the combination of a hybrid 2D pulse and a refocusing chirp pulse in the presence of large (˜200 Hz) field inhomogeneities. The pulse sequence is shown in FIG. 8A.

FIG. 12A: Simultaneous chemical shift and slice selection in an imaging experiment by applying a pair of frequency-swept pulses with opposite gradients—slice-selection by frequency-sweeps with opposite gradients;

FIG. 12B: transverse magnetization across the slice.

FIG. 13A: Amplitude and frequency modulations calculated for representative SLR excitation pulses of the present invention, illustrated for swept chirps of identical nominal duration Tₑ=10 ms and bandwidth ΔO=4.5 kHz. The SLR pulses are then ascribed frequency sweeps of variable durations; e.g., T′ₑ=3 ms (gray line) or 5 ms (black line);

FIG. 13B, FIG. 13C: Resulting spatial, spectral profiles arising upon implementing Bloch simulations based on the quadratic-phase SLR pulses, for the two chosen parameters.

FIG. 14A: Reference image of examined water/fat phantom with no spectral or in-slice spatial selectivity;

FIG. 14B, FIG. 14C: Spin-echo images illustrating the spatial and spectral selectivity achievable by spatiotemporal encoding, obtained with the sequence shown in FIG. 14D;

FIG. 14D: Pulse sequence.

FIG. 15A: Slice-selective spin-echo imaging of the water/fat phantom of FIG. 14A—simultaneous water/fat echoes formed upon using the sequence shown in FIG. 14D, with Gₑ=Gᵣ and quadratic-phase SLR 90/180° pulses;

FIG. 15B, FIG. 15C: Separated, concurrent water (FIG. 15B) and fat (FIG. 15C) images collected using the sequence shown in FIG. 15E, incorporating Gᵣ=−Gₑ and a fat echo forming 2 ms after the water echo by playing a gradient lobe in the slice-selection dimension and reversing the readout gradient;

FIG. 15D, FIG. 15E: Pulse sequences.

FIG. 16A: Slice-selective spin-echo imaging of a water/fat phantom consisting of four water-containing spheres immersed in oil. A comparison is made between a reference image without fat suppression;

FIG. 16B: an image obtained using fat-suppressed sequences based on the Dixon sequence;

FIG. 16C: an image obtained using the SPAIR sequence; and

FIG. 16D: an image obtained using the SPEN-based SPSP sequence of the present invention;

FIG. 16E: A comparison between the spectral selectivity of the SPEN-SPSP of the present invention and the SPAIR sequence;

FIG. 16F: SPEN-based pulse sequence.

FIG. 17A: Multi-shot spin-echo axial or sagittal imaging of human breast at 3T. A comparison is made between a reference image with no fat suppression;

FIG. 17B: an image obtained using the SPAIR-based sequence; and

FIG. 17C: an image obtained using the SPEN-based SPSP sequence of the present invention incorporating fat suppression.

FIG. 18A: Breast spin-echo EPI axial or coronal images collected at 3T using: a scanner-supplied SPSP 2D pulse for slice-selective water excitation;

FIG. 18B: the SPEN-based SPSP selectivity using the sequence shown in FIG. 18D;

FIG. 18C: Concurrent single-shot spin-echo EPI water and fat images collected using the SPEN-based SPSP sequence shown in FIG. 18E. FIG. 18D, FIG. 18E: Pulse sequences.

FIG. 19A: Single-shot spectroscopic imaging, using the SPEN-based spectral-spatial selectivity, illustrated on a water (outer)/acetone (inner) phantom—reference multi-shot spin-echo image with no spectral selectivity;

FIG. 19B: Single-shot spin-echo EPI image with no spectral selectivity;

FIG. 19C: Spectroscopic images of water and acetone obtained in a single shot using spin-echo EPI with the SPEN-based SPSP selectivity;

FIG. 19D: Pulse sequence for single-shot spectroscopic imaging using a pair of frequency-swept pulses for spatiotemporal encoding.

FIG. 20A: Localized spectroscopy in a non-cubic voxel, illustrated on a water (outer)/acetone (inner) phantom—spectra obtained from a cylindrical voxel centered on the tube of acetone with a low-bandwidth (gray) and a high-bandwidth (black) 2D excitation pulse;

FIG. 20B: Module for localization in a non-cubic voxel;

FIG. 20C: Reference multi-shot spin-echo images obtained with no in-slice spatial selectivity;

FIG. 20D: Reference multi-shot spin-echo images obtained with in-slice selection of a circular region using a hybrid 2D pulse.

FIG. 21A: Sculpting of a three-dimensional shape with the use of a pair of hybrid 2D refocusing pulses, illustrated on a water (outer)/acetone (inner) phantom—reference multi-shot spin-echo image with no in-slice selectivity;

FIG. 21B: Multi-shot spin echo image obtained after a spectrally selective excitation pulse and a pair of hybrid 2D refocusing pulses that selects a triangle in-slice and a square in the slice/readout plane;

FIG. 21C: Series of multi-shot spin-echo images obtained with the same selectivity as in FIG. 21B for several slice locations with a reduced field of view;

FIG. 21D: Pulse sequence to sculpt a three-dimensional shape for a selected chemical and subsequently visualize a slice of the shaped region.

FIG. 22: Proposed pulse sequence element for simultaneous 3D spatial and 1D spectral selectivity (4D spatial-spatial-spatial-spectral selectivity). A pair of hybrid refocusing pulse is used to sculpt a three-dimensional shape, as described in FIGS. 21A-21D. The sign of the blipped gradient is changed between the first and the second refocusing pulse, to afford for a simultaneous spectral selectivity, as described in FIGS. 14A-19D.

### DETAILED DESCRIPTION OF THE INVENTION

The present invention provides a new family of pulses that exploit the principles of spatiotemporal encoding in order to obtain multidimensional selectivity with improved performance. The pulses of the present invention use continuous or discretized frequency sweeps for the sequential manipulation of the spins in space in one dimension or more. Selectivity is achieved in two dimensions or more concurrently. Disclosed herein is the concurrent selectivity in spatial, spectral, displacement-based, and/or relaxation-based dimensions. The pulses of the present invention are significantly less demanding on hardware and timing accuracy than the hitherto used pulses and provide high definition magnetic resonance images of arbitrarily shaped objects and/or high resolution spectra of desired components within said objects.

The present invention is based in part on the unexpected finding that SPEN concepts, as disclosed in WO 2004/011899, WO 2005/062753 and WO 2007/078821 (the contents of each of which are hereby incorporated in their entirety), can be used to design shaped pulses which operate in a direct rather than in the usual reciprocal k-space in at least one dimension. These pulses can be used to excite the spins in a single scan in an arbitrarily shaped region of interest by designing the waveform of the pulse to reflect the sampling of a frequency-modulated pulse. Surprisingly, these pulses can also be used to add spectral selectivity to a spatially sculpted excitation. In contrast to classic 2D SPSP pulses, the method of the present invention does not require fast oscillating gradients and the spatial selectivity imparted by the pulses is not limited to shapes which are defined by the intersection of two 1D selectively excited regions. Thus, using the method of the present invention, any conceivable geometry or architecture can be excited to afford imaging thereof or localized magnetic resonance spectroscopy therein. According to the principles of the present invention, spectral selectivity can be obtained for a single chemical species wherein the contribution of other chemical species is being suppressed. Alternatively, the method of the present invention can be used for the concurrent acquisition of slice-selective images of multiple chemical species (spectroscopic imaging). Within the scope of the present invention is the use of the method disclosed herein to significantly reduce chemical shift displacement in localized spectroscopy. The method achieves spectral/spatial selectivity without leading to multiple spectral excitation sidebands.

According to the principles of the present invention provided herein is a method for producing multidimensional selectivity in magnetic resonance imaging or spectroscopy. In particular, the present invention provides a method of obtaining a magnetic resonance image having selectivity in two dimensions or more. The method comprises the application of a frequency-swept irradiation in one dimension or more, said irradiation is concurrently applied with at least one magnetic field gradient that affords the partitioning of a sample into a set of subensembles of spins, each subensemble precesses with a different resonance frequency. Thus, the application of a frequency-swept irradiation in one dimension or more provides a time-incremented sequential manipulation of each subensemble in said dimension. The irradiation applied is typically a polychromatic irradiation in the form of an RF pulse whose waveform can be designed using various algorithms as is known in that art. As disclosed herein, following irradiation, a signal can be acquired with no further manipulation using the SPEN-based acquisition. Alternatively, in order to afford the acquisition using conventional schemes including, but not limited to, gradient echo, spin echo, fast low angle shot (FLASH), fast spin echo (FSE), or echo planar imaging (EPI), the application of at least one other frequency-swept irradiation with or without magnetic field gradients or the application of an additional gradient pulse is required. This optional step provides the removal of undesired phase or aliasing imparted to the various subensembles during excitation or the additional manipulation of a desired subensemble of spins. It will be appreciated by one of skill in the art that the manipulation of spins typically comprises at least one of excitation, crushing, inversion, refocusing and storage. Each possibility represents a separate embodiment of the present invention.

For a better understanding of the invention and to show how it may be carried into effect, reference will now be made, purely by way of example, to the accompanying drawings. With specific reference now to the drawings in detail, it is stressed that the particulars shown are by way of example and for purposes of illustrative discussion of the preferred embodiments of the present invention only, and are presented with the purpose of providing what is believed to be the most useful and readily understood description of the principles and conceptual aspects of the invention. In this regard, no attempt is made to show structural details of the invention in more detail than is necessary for a fundamental understanding of the invention; the description taken with the drawings making apparent to those skilled in the art how the several forms of the invention may be embodied in practice.

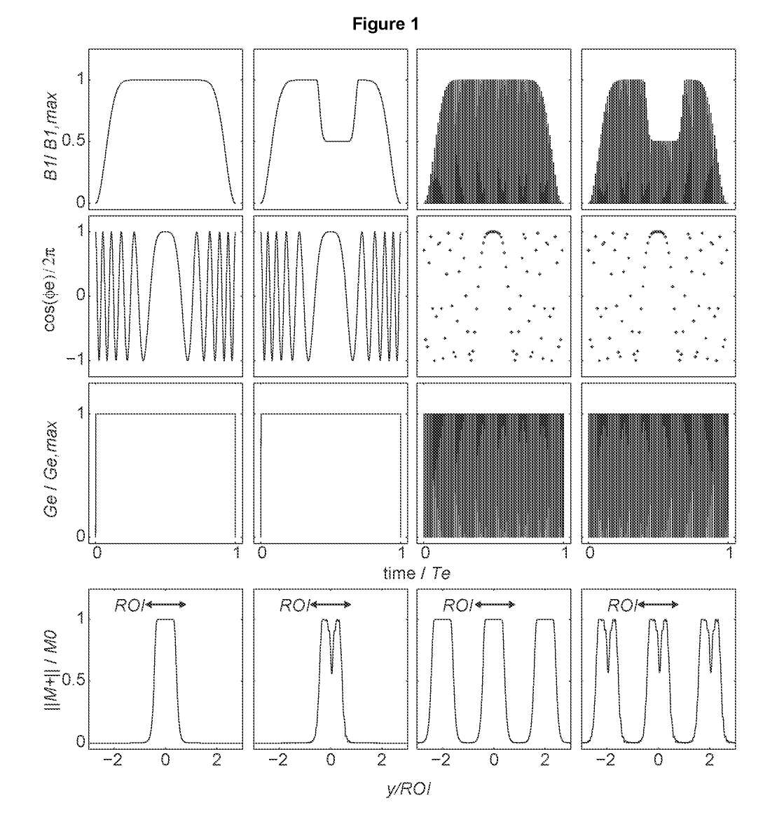

NMR imparts 1D spatial selectivity by applying a shaped RF waveform in unison with an external magnetic field gradient. In typical excitation schemes, RF pulses manipulate all the frequency elements within a targeted Region of Interest (ROI) simultaneously. In contrast, in SPEN-oriented excitation pulses, spins across the sample are sequentially manipulated by the combined action of a magnetic field gradient and a frequency-swept RF. In the simplest description of these pulses, spins are acted upon instantaneously when the carrier frequency of a linearly-swept (“chirp”) RF pulse matches their resonance frequency, and precess freely otherwise (Pipe, Magn. Reson. Med. 33 (1995) 24-33). When a constant-amplitude profile is used, the ensuing RF waveform can be written in the usual rotating frame as follows:

$${B}_{1} ( t ) = {B}_{1}^{0} exp [ i ( {O}_{i , e} t + \frac{{R}_{e} {t}^{2}}{2} + {φ}_{0} ) ] = {B}_{1}^{0} exp [ i {φ}_{e} ] \qquad ( 1 )$$

where B₁⁰, φ₀, Rₑ and O_{i,e} are the RF amplitude, an arbitrary initial phase (set henceforth to zero), the constant sweep rate and the initial carrier frequency offset of the excitation pulse, respectively. This approach leads to a uniform excitation of an initially longitudinal magnetization M_{z}, into a post-excitation transverse magnetization ∥M₊∥. The effective nutation angle 0≦θ≦π associated with this sweep can be set according to the B₁⁰ value chosen, and the post-excitation phase of the spins can be well approximated by the following quadratic equation:

$${φ}_{exc} ( y ) = ( - \frac{{( {γG}_{e} )}^{2}}{2 {R}_{e}} ) {y}^{2} + ( {γG}_{e} ( {T}_{e} + \frac{{O}_{i , e} - Ω}{{R}_{e}} ) ) y + ( Ω {T}_{e} - \frac{{( {O}_{i , e} - Ω )}^{2}}{2 {R}_{e}} - \frac{π}{2} ) \qquad ( 2 )$$

where Gₑ is the amplitude of a gradient applied along the ŷ-axis, Tₑ is the overall duration of the pulse, and Ω is a site-specific frequency offset associated with chemical shift or field inhomogeneity effects (Pipe, Magn. Reson. Med. 33 (1995) 24-33; Tal et al., Prog. Nucl. Magn Reson. Spectrosc. 57 (2010) 241-292; Kunz, Magn. Reson. Med. 3 (1986) 377-384; Kunz, Magn. Reson. Med. 4 (1987) 129-136; and Pipe, Magn. Reson. Med. 36 (1996) 137-146). In practice, the amplitude modulation of the frequency-swept pulse is not strictly constant, as some smoothing is usually applied to avoid the ringing induced by the finite duration of the pulse. Such smoothing of the waveform can be achieved with a WURST-like envelope, transitioning outside the targeted ROI and leaving the excitation phase in Eq. 2 essentially unchanged. If the effects of the a priori unknown offset Ω can be disregarded (or if its value as a function of ŷ is known) the excitation of a sculpted ∥M₊∥(y) is straightforward, by imparting a time-dependency B₁⁰(t) to the amplitude of the chirp pulse as the RF manipulates various y-dependent positions, as illustrated in FIG. 1 (two left columns) At times t this pulse imparts on the corresponding y(t)

$$y ( t ) = \frac{( {O}_{i , e} - Ω ) + {R}_{e} t}{γ {G}_{e}} \qquad ( 3 )$$

a nutation angle θ(t), which depends on the shape of B₁⁰.

Thus, according to some aspects and embodiments, the frequency-swept pulse utilized by the method and system of the present invention is continuous. In certain embodiments, the frequency-swept pulse is substantially linear (“chirp”).

According to other aspects and embodiments, the frequency-swept pulse utilized by the method and system of the present invention is discretized. In discretized frequency-swept pulses, the finely modulated RF pulse acting in the presence of a constant gradient is replaced by an alternation of Nₑ square pulses acting in the absence of gradients interleaved with Nₑ gradient “blips” acting on freely evolving spins between the pulses. Both of these events are clocked out at a common rate Δt⁻¹=Nₑ/Tₑ. The integrated area and the phase of the j^{th} square pulse is provided by B₁⁰(tⱼ)Tₑ/Nₑ and φⱼ, respectively, where tⱼ=jΔt; and the blipped gradients are considered as being identical and square with integrated areas of Δkₑ(γGₑTₑ)/Nₑ each. FIG. 1 (two right columns) illustrates an exemplary discretization process and its effects on the ensuing sculpting. The time-bandwidth product of the pulses is Q=40 with Nₑ=80 steps, resulting in the excitation of periodic sidebands with a replication length of (Nₑ/Q)ROI=2ROI. The main consequence of the discretization is the periodic replication of the excited magnetization profile (FIG. 1, bottom row). These replicas become increasingly closer as the number of Nₑ, events decreases. This effect reflects the fact that any two spin-packets for which the gradient-derived precession phase varies by a multiple of 2π at any given Δt step appear indistinguishable when acted upon by the subsequent RF pulse. It is noteworthy that in contrast to traditional DANTE pulses (Morris et al., J. Magn. Reson. 29 (1978) 433-462) or to “gapped” (Idiyatullin et al., J. Magn. Reson. 193 (2008) 267-273), the precession and nutation steps are entirely separated in the disclosed implementation. This is similar to the PINS approach (Norris et al., Magn. Reson. Med. 66 (2011) 1234-1240), and explains the identical intensities elicited (at least in such fully broadband simulations which are unaffected by instrumental limitations) by all excitation center-/side-bands.

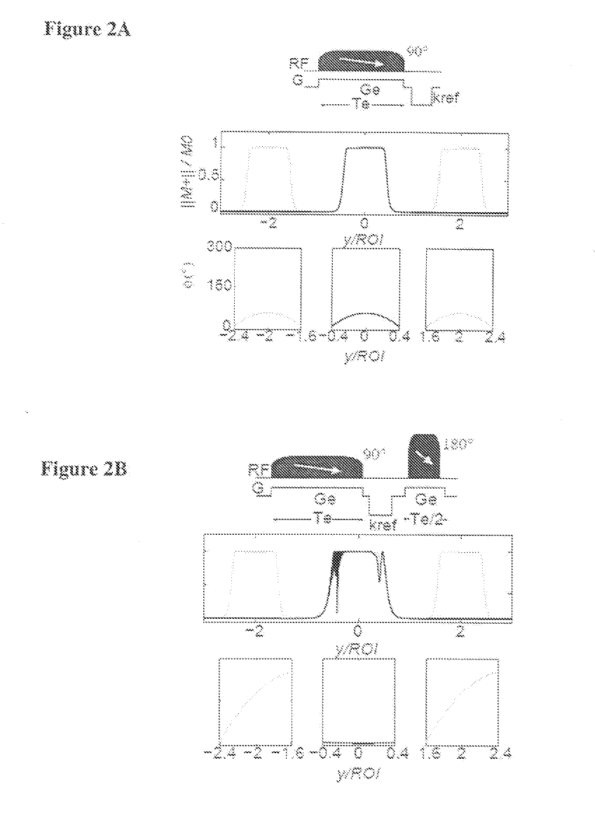

FIGS. 2A-2B illustrate the magnetization profile that is excited by a discretized chirp pulse. The excitation chirp pulse has a time-bandwidth product Q=100 and is either continuous or discretized with Nₑ=200 steps. Discretization results in the excitation of periodic sidebands with a replication length of (Nₑ/Q)ROI=2ROI. The two pulses are applied under identical gradient amplitudes and sweep over identical regions of length ROI. Similarly to the use of a continuously swept pulse (Eq. 2), the discretized excitation also imparts an approximately quadratic phase profile to the transverse magnetization. The quadratic phase profile exists not only in the central band being sought, but also in the excitation sidebands that flank it. When the excitation sidebands fall outside the targeted ROI, they can be ignored. The originating signal can be suitable for SPEN-based MRI without further manipulation. In particular, signals in SPEN experiments originate from points of the sample that correspond to an extremum of the spatially varying parabolic phase (Chamberlain et al., Magn. Reson. Med. 58 (2007) 794-799; Shrot et al., J. Magn. Reson. 172 (2005) 179-190; Tal et al., J. Magn. Reson. 182 (2006) 179-194; and Tal et al., Prog. Nucl. Magn Reson. Spectrosc. 57 (2010) 241-292); this “stationary point” progresses as an acquisition gradient Gₐ is applied, rasterizing the response of the full sample as the acquisition time reaches Tₐ=|GₑTₑ/Gₐ|. For conventional k-space-based acquisitions, the parabolic phase associated with a continuous or discretized chirp pulse needs to be removed to provide a Fourier-based MRI. In particular, Fourier transformation of the signal acquired from a magnetization with a quadratic-phase, a so-called “pseudo-echo”, provides an image without aliasing only when the quadratic phase does not involve frequencies larger than γG₁FOV, where Gₐ is the acquisition gradient and FOV is the field of view (Park et al., Magn. Reson. Med. 55 (2006) 848-857). A simple strategy for removing the quadratic phase imparted by an excitation chirp pulse, while preserving its B₁⁰-imparted profile, comprises the use of a suitably defined frequency-swept refocusing pulse following excitation (Tal et al., Prog. Nucl. Magn Reson. Spectrosc. 57 (2010) 241-292; Kunz, Magn. Reson. Med. 3 (1986) 377-384; Kunz, Magn. Reson. Med. 4 (1987) 129-136; and Bohlen et al., J. Magn. Reson. 84 (1989) 191-197). Pairs of frequency-swept pulses suitable for volume selection in localized spectroscopy are described in e.g. Keevil, Physics in Medicine and Biology 51 (2006) R579-R636. Generalized hyperbolic secant and adiabatic SLR pulses suitable for performing slice selection in imaging experiments are described in e.g. Park et al., Magn. Reson. Med. 61 (2009) 175-187; and Balchandani et al., Magn. Reson. Med. 67 (2012) 1077-1085. The phase accrued after applying an adiabatic 180° swept pulse can be written in the following Eq. 4:

$${φ}_{ref} ( y ) = {φ}_{exc} ( y ) + ( - \frac{{( γ {G}_{r} )}^{2}}{{R}_{r}} ) {y}^{2} + ( γ {G}_{r} ( {T}_{r} + \frac{2 ( {O}_{i , r} - Ω )}{{R}_{r}} ) ) y + ( Ω {T}_{r} - \frac{{( {O}_{i , r} - Ω )}^{2}}{{R}_{r}} ) \qquad ( 4 )$$

where Tᵣ, Rᵣ, O_{i,r} and Gᵣ are the duration, the sweep rate, the initial carrier frequency and the concurrent gradient associated with the 180° refocusing pulse, respectively; φ_{exc} is an initial phase provided by Eq. 2 or a “discretized” version thereof. For simplicity, it is contemplated that the refocusing pulse is always played out continuously. Thus, when the refocusing chirp pulse follows the excitation chirp pulse and addresses the same ROI, setting TₑGₑ=2TᵣGᵣ affords the removal of the quadratic phase dependence of the φ_{ref} in Eq. 4 entirely. In particular, FIGS. 2A-2B demonstrate how the simple choice of parameters Tₑ=2T_{f} and Gₑ=Gᵣ succeeds in removing the contribution of the quadratic phase off the targeted ROI, thus affording analysis using conventional k-space Fourier imaging. The duration of the (continuous) refocusing chirp pulse is half that of the excitation chirp pulse, so as to cancel the quadratic phase of the centerband at its conclusion. An additional gradient lobe of area k_{ref}=−GₑTₑ/2 is inserted to cancel the linear phase of the centerband. The distortions of the ROI in FIG. 2B correspond to the transition region of the refocusing pulse, and their contributions to the signal can be suppressed with crusher gradients. Of note, as a result of the double-sweep: (i) the linear phase contribution previously arising from the chemical shifts is removed; (ii) when using a discretized version of the 90° chirp pulse, the quadratic phase contributions that previously affected the excitation sidebands are removed by the 180° post-excitation adiabatic sweep only for the fraction of the sidebands that is swept over by the refocusing pulse.

The MRI signal to be acquired should originate from the targeted ROI; i.e., from the centerband and not from the sidebands. For either k-space-based or SPEN-based MRI acquisitions, the signal detected after a discretized excitation can include contributions arising from undesirable excitation sidebands. In order to avoid undesirable excitation sidebands, potential sources of interference arising from voxels outside the ROI can be pre-saturated. Alternatively, the discretized pulse can be designed so that the excitation sidebands fall outside the sample. In another alternative, a refocusing pulse can be applied selectively on the centerband and not on the sidebands (Rieseberg et al., Magn. Reson. Med. 47 (2002) 1186-1193; and Busch et al., Magn. Reson. Med. 68 (2012) 1383-1389). Requesting that the excitation sidebands fall outside a pre-defined ROI sets bounds on the properties of the discretized RF pulse and on its associated gradient. For the SPEN-based pulses of the present invention, a given chirp excitation bandwidth Δv=(O_{f,e}−O_{i,e})/2π defines the ROI as 2πΔv/γGₑ. The separation ΔL at which the excitation sideband appears replicated can in turn be related to the interval Δt=Tₑ/Nₑ that separates the sub-pulses of the discretized chirp pulse, according to γGₑΔL=2π/Δt. The condition for the excitation sidebands to appear separated from the centerband is thus ΔL>ROI, or alternatively

$$\frac{Ne}{Δ v \cdot Te} > 1 ⇔ Ne > Q = Δ v \cdot Te \qquad ( 5 )$$

According to Eq. 5, the number of subpulses in the discretized pulse should be larger than the time-bandwidth product Q=Δν·Tₑ of the corresponding excitation chirp pulse. This time-bandwidth product is a dimensionless measure of the pulse's performance Thus, for a chirp pulse, the selectivity of the pulse improves as Q increases. In addition, the curvature of the quadratic-phase parabola imprinted on the spins by a swept pulse is proportional to Q. Typically, Q is in the range of 50-100 although lower Q values can be tolerated. Of note is that if Q<20, the assumption of a progressive excitation underlying the use of chirped excitations begins to break down.

Another manner to avoid the overlapping of the excitation sidebands with the central ROI being targeted without employing a large number of Nₑ steps or very long pulse lengths Tₑ, is by reducing the chirped bandwidth Δν. For a given ROI, Eq. 5 indicates that this can be achieved by reducing the associated gradient amplitude Gₑ such that

$$Ge < \frac{2 π Ne}{γ ROI \cdot Te} \qquad ( 6 )$$

Similar bounds on the gradient amplitude are known for Fourier-based discrete pulses (Rieseberg et al., Magn. Reson. Med. 47 (2002) 1186-1193). However, weakening the gradients as demanded by Eq. 6 may result in a pulse which is susceptible to distortions, particularly those arising from susceptibility and chemical-shift effects.

The present invention provides a method of overcoming these limitations by providing discretized SPEN pulses, in which the contribution of the centerband and sidebands can be separated using a single conventional scan. The method of the present invention can be performed even in instances where a significant overlap between the centerband and sidebands exists. By utilizing the method disclosed herein, intense gradients can be employed, thus affording high immunity against undesirable frequency offsets.

Although the method of the present invention is primarily directed to multidimensional pulses, the physical basis of a one-dimensional pulse is provided for simplicity. Under the effects of a discretized excitation, the total magnetization excited by a pulse assuming that the flip angle is small enough for all positions is described in Eq. 7 as a sum over bands as follows:

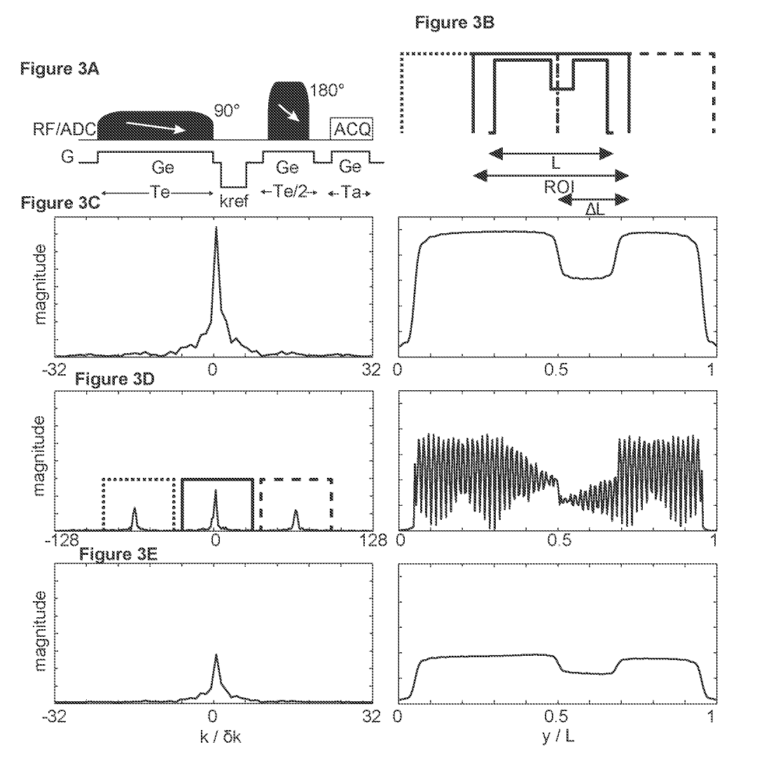

M(y)=ΣₚMp(y) (7)

where for simplicity the index p=0 denotes the centerband; i.e., the ROI being sought. In practice, the sum could be restricted to bands that fall within the sample. Owing to the small-flip angle assumption, the excited magnetization is linear with respect to B₁ even when the various excited bands overlap. The sideband amplitude is an identical replica of the centerband amplitude. However, the phase of the sideband is provided by the following equation:

$${M}_{p} ( y + p Δ L ) = \vert {M}_{0} ( y ) \vert \cdot exp \{ i [ {φ}_{0} ( y ) + p ( \frac{{( γ {G}_{e} )}^{2}}{{R}_{e}} Δ L ) y ] \} , \qquad ( 8 )$$

where φₒ(y) is as provided in Eq. 2, all remaining parameters are as described hereinabove, and constant phase terms have been disregarded. Eq. 8 highlights the fact that, while all bands share an identical quadratic contribution in their phases, they differ by a linear phase coefficient. Thus, the contribution of the centerband to the signal can be separated from the contribution of the sidebands when, following the excitation process, the quadratic phase terms are removed (for instance by the application of a suitable 180° adiabatic chirp pulse as herein disclosed). Each band then forms its own individual echo at a distinct location in k-space. FIGS. 3A-3D illustrate one non-limiting manner of separating the contribution of the centerband from that of the sidebands, for the case of overlapping bands arising due to a discrete excitation that breaks the condition of Eq. 6 (i.e., when the centerband and the sidebands overlap). The pulse sequence in FIG. 3A is a 1D spin-echo MRI experiment involving a discretized version of the 90° chirp pulse/gradients. This pulse sequence is utilized for imaging a phantom of size L (FIG. 3B). The discrete excitation chirp pulse has a time-bandwidth product Q=200. The two pulses use the same gradient amplitude and sweep over the same region of interest of length ROI=1.5L. The duration of the refocusing chirp pulse is half that of the excitation chirp pulse, such that the quadratic phase of the centerband is cancelled at the end of the refocusing pulse. The signal and its Fourier transform (FT) are shown in FIG. 3C for a continuous excitation chirp pulse, illustrating the feasibility of Fourier imaging after a pair of chirp pulses. The signal and FT shown in FIG. 3D correspond to an excitation chirp pulse discretized with Nₑ=100 steps. As the amplitude of the discretized excitation chirp pulse is chosen such that it is in the linear regime, each echo in FIG. 3D corresponds to a band excited by the discretized chirp pulse, as indicated by the dashed and continuous lines shown in FIG. 3B, 3D. FIG. 3E illustrates the recovery of the image of the ROI. In particular, the central echo of the signal shown boxed in a continuous line in FIG. 3D, consisting of 64≃Nₑ*(L/ROI) points, is filtered from the full signal. In this non-limiting example, the post-excitation 180° refocusing pulse removed the quadratic phase for the center- and for the overlapping side-bands; as per Eq. 8, these bands still differ by a linear term of the form

$$p ( \frac{{( γ {G}_{e} )}^{2}}{{R}_{e}} Δ L ) y = {pN}_{e} ( \frac{y}{ROI} ) .$$

As a result of this difference a linear gradient applied before or after the refocusing pulse leads to a distinct echo for each band; the contribution of the centerband can thus be retrieved by a simple k-domain weighting fashion, despite the overlap with the sidebands. Thus, the use of a post-excitation 180° refocusing pulse allows the increase of the gradient amplitude Gₑ associated with the spatial selectivity and to improve the robustness of the RF pulse against field inhomogeneities while eliminating the overlapping between the centerband and the sidebands. Of note is that preserving the linear approximation implicit in Eq. 7 implies that only a fraction of the magnetization in the ROI being excited corresponds to the undistorted centerband being sought. The remaining portion of the magnetization corresponds to harmonics of the excitation sidebands, that overlap with the centerband and thus its imaging information is not faithful.

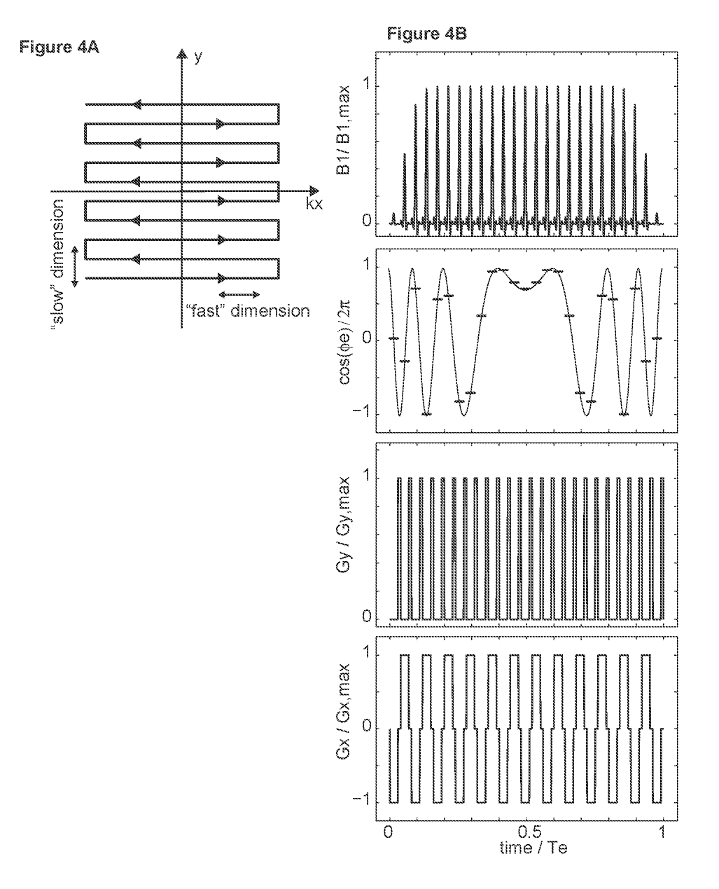

The principles outlined herein can thus be extended to multiple dimensions. According to certain aspects and embodiments, the present invention provides a method of producing two-dimensional spatial excitation of the spins by concurrently applying during excitation, at least one other magnetic field gradient being configured to impart spatial selectivity within the subensembles of spins using a predetermined k-space trajectory. In other words, the method utilizes a frequency-swept SPEN-based strategy to shape the spatial profile along one dimension, while a conventional Fourier-based analysis imparts the excitation shape being sought along an orthogonal dimension. Such a “hybrid” direct-plus-reciprocal excitation space can, for example, be explored using the blipped Cartesian trajectory illustrated in FIG. 4A, where the SPEN dimension is the y spatial axis and the Fourier dimension is the x spatial axis. In particular, a chirped-like SPEN encoding as disclosed herein is implemented along the “slow” (low-bandwidth) dimension in a discrete manner, while a k-space Fourier-designed waveform is used to impart spatial selectivity along the second, “fast” (high-bandwidth) dimension. An illustrative waveform is shown in FIG. 4B, where all the subpulses were chosen as identical sinc pulses, with an overall phase and amplitude modulation of the pulse train that corresponds to a discrete, linear frequency-sweep. Such an approach is similar to the “separable” design originally introduced to obtain adiabatic 2D pulses (Conolly et al., Magn. Reson. Med. 24 (1992) 302-313) which has also been used to develop other families of pulses based on an echo-planar trajectory, the so-called “echo-planar pulses” (Pauly et al., Magn. Reson. Med. 29 (1993) 776-782; and Pauly et al., Magn. Reson. Med. 29 (1993) 2-6). Following the model of adiabatic 2D pulses, the alternating polarity of the “fast” gradient for even and odd subpulses makes each pulse inherently refocused; the 2D pulse thus behaves in the slow dimension as if its constituent subpulses were square pulses. This enables a considerable simplification in the design of the pulse-driven magnetization sculpting, as the shapes to be imparted along the two dimensions can be treated independently. Of note is that the 2D pulse introduced herein can be seen as operating in a hybrid direct (y) and reciprocal (k_{g}) space, in contrast to Fourier 2D pulses which operate entirely in a 2D reciprocal space.

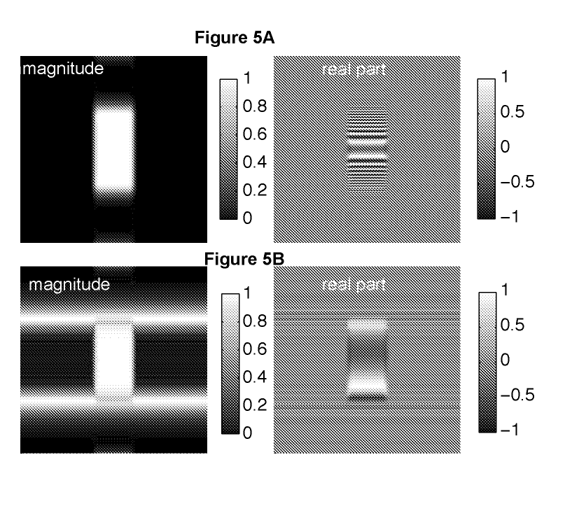

FIGS. 5A-5B show numerical non-limiting examples of magnetization excited with an exemplary hybrid 2D pulse of the present invention. The waveform of the hybrid 2D pulse comprises a train of sinc subpulses with a phase and amplitude given by that of the discretized chirp pulse. FIG. 5A shows a finely digitized pulse acted uniformly along the slow dimension, thus imprinting a quadratic phase of the kind usually desired in SPEN imaging. In the fast dimension, all the subpulses were imparted as k-domain sinc shapes, leading the excitation of a slab of width ROIₓ along this dimension. FIG. 5B shows a variation of this excitation mode, incorporating 180° sweep following the 2D hybrid excitation. The 180° pulse was surrounded with crusher gradients and an additional gradient lobe of area −GₑTₑ/2 (cf. FIG. 3A), leading to cancelations of both the quadratic and linear phase distortions. As discussed for the 1D case, suitable timing of this adiabatic sweep can remove the quadratic phase dependence and enable conventional imaging. Similar to the 1D case, multiple sidebands are generated when using a coarser increment for the SPEN (either due to an increase in the time step intervals or a reliance on a larger Gₑ gradient). According to the principles of the present invention, these excitation replicas arising along the “slow” dimension can be separated and filtered out by tailoring the 180° adiabatic refocusing conditions.

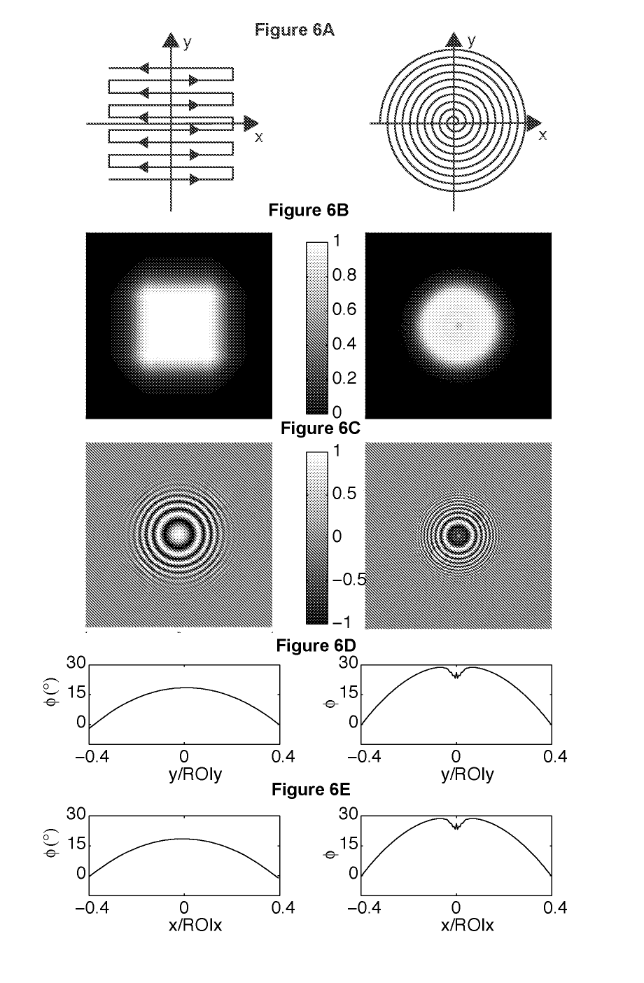

Another alternative embodiment of the present invention is the use of a purely SPEN-based strategy. Such an approach would impart a 2D excitation shape by performing a time-incremented, sequential excitation of the spins along a predefined 2D spatial trajectory which can be a Cartesian trajectory, a spiral trajectory or a radial trajectory. Each possibility represents a separate embodiment of the present invention. It is contemplated that some of the benefits of SPEN-sculpting in 1D, such as the possibility to actively compensate for field inhomogeneities in a voxel-by-voxel manner, could be extended to a higher-dimensional space. FIGS. 6A-6D illustrate two embodiments of the present invention that allow obtaining purely SPEN-based 2D RF pulses, based on a rasterized excitation using Cartesian and spiral trajectories. In both cases, the RF pulse was designed in analogy with the 1D frequency-swept considerations described hereinabove; i.e., by defining the desired trajectory first in k-space, k(t), and applying an RF pulse with a phase-modulation of the form φ_{exc}=(½) λ∥k∥², where X is a constant. Such a phase modulation corresponds to a frequency modulation of the form ω=λ\dot{k}·k=γG·λk, where the variable r=λk can be identified as the trajectory along which the spins are excited during the SPEN 2D pulse. These relations can be visualized for the blipped Cartesian trajectory in FIG. 6A where each subpulse along the “fast” x-axis becomes a chirped RF with parameters corresponding to its suitably signed (+G_{e,x} or −G_{e,x}) excitation gradient and endowed with the desired amplitude profile, whereas increments along the “slow” y-axis are accounted by G_{y} “blips” and discretized amplitude/phase factors similar to those described hereinabove for the hybrid 2D (y/kₓ) pulse. It should be understood that due to the discretization procedure, the various sideband-related treatments that have been described for the hybrid case can also be implemented for this embodiment.

In another non-limiting exemplary embodiment, the spins are excited along a spiral trajectory. In accordance with these embodiments, an Archimedean spiral with N turns and total duration T as illustrated in FIG. 6A is provided. The k-space trajectory is written in the following manner:

Kₓ=γG₀t cos(ω_{G}t),K_{y}=γG₀t sin(ω_{G}t) (9)

where G₀ and the angular velocity were set constant for simplicity. This results in the use of a quadratic RF excitation phase

φ=½G₀v₀t² (10)

where v₀ is a constant representing an “average velocity” in which points being manipulated at a given time move away from the center. The sequential excitation of the spins then occurs along the trajectory:

rₓ=v₀t cos(ω_{G}t),r_{y}=v₀t sin(ω_{G}t (11)

The excitation profile in this spiral case is similar to that of the blipped Cartesian case. In particular, each turn of the spiral corresponds to a subpulse that sweeps continuously over the angular variable 0, while a discrete sweep over the variable r occurs over consecutive arms. The total diameter of the excited disc is provided by 2Rₓ =2Tvₒ, which acts as an “effective ROI” for spiral excitations. As described in the 1D case, the use of a discrete number N of spiral turns implies that “excitation sidebands” are generated in an outward radial fashion. Avoiding overlap of such concentric rings with the ROI of 2Rₓ places an upper bound on the gradient strength to be used as follows:

$${G}_{0} < \frac{2 π N}{γ 2 Rx \cdot T} \qquad ( 12 )$$

similar to Eq. 6. The time-bandwidth product is defined as Q=2TₑG₀Rₓ.

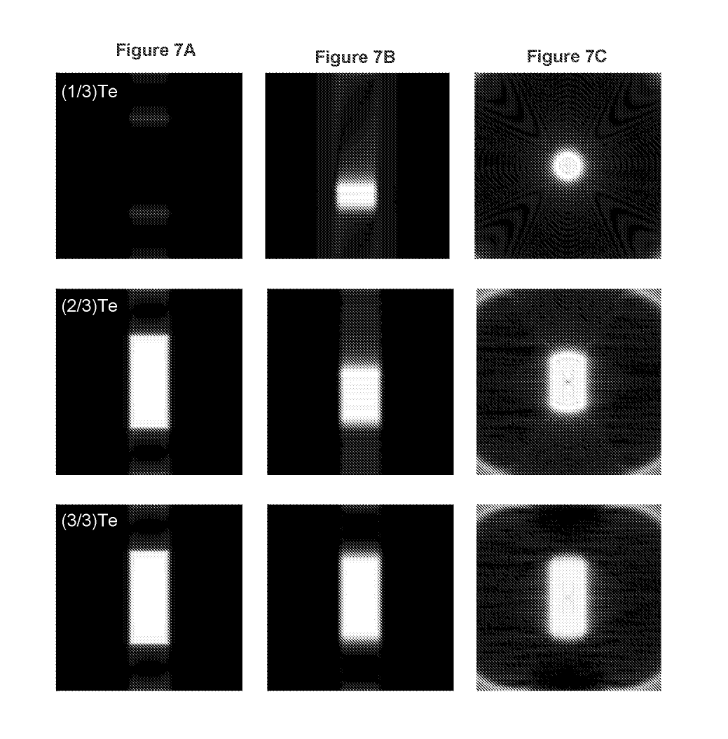

Hence, the present invention provides 2D pulses using hybrid k/r-space or purely-SPEN spiral pulses to afford the excitation of spins in an arbitrary shape in two dimensions. The excitation of spins can be performed in several scans or in a single scan. FIGS. 7A-7C show a sequence of photographs obtained at 33, 66 and 100% throughout the course of each of these pulses. A blipped Cartesian trajectory with Nₑ=150 lines was used for the Fourier and the hybrid pulse, with a time-bandwidth product in the slow dimension of Q=100, and sinc subpulses in the fast dimension. For the SPEN pulse, a spiral with Nₑ=150 turns and a time-bandwidth product of Q=100 was used. These photographs show that whereas a classic k-space pulse excites the high-frequency and subsequently all gross features of the shape rapidly followed by the sculpting of the finer features globally, the spatially encoded pulses rasterize the excitation sculpting throughout the course of their frequency sweeps.

Thus, the method disclosed herein can be extended to excitation of spins using the SPEN-based strategy in three or more dimensions while imparting spatial-spatial selectivity. According to these embodiments, multidimensional magnetic resonance imaging of objects characterized by complex architectures can be afforded. In other embodiments, the present invention further provides multidimensional magnetic resonance imaging of a region of interest within an object, wherein said region of interest is characterized by complex architectures. The method of the present invention can employ larger excitation gradients upon imprinting the desired spatial pattern along the “slow” axis, thus affording a higher robustness against field inhomogeneities and/or chemical shift miss-registrations.

It should be understood that the choice of the readout dimension in imaging for the discretized dimension in irradiation constitutes one non-limiting configuration in which the method of the present invention can be implemented. This configuration has been used to obtain an image of the excited region and illustrate the self-unfolding mechanism. Other configurations include, but are not limited to, using frequency-swept pulses along the phase-encoding or the slice-selecting dimensions. It is contemplated that using alternative configurations may even afford additional advantages from the self-unfolding procedure herein disclosed. Without being bound by any theory or mechanism of action, it is construed that since the presence of additional echoes limits the resolution in the frequency-swept dimension, when this dimension is imaged, a tradeoff exists between the number of subpulses in the discretized chirp pulse and the obtained resolution. This compromise may be avoided in the other dimensions.

According to certain aspects and embodiments, the present invention provides multidimensional pulses with a spatial-spectral selectivity. The concepts of spatial-spectral selectivity using the pulses of the present invention are outlined herein. It is contemplated that the application of a chirp pulse lasting a time Tₑ, sweeping a range of offsets ΔO while spins of a given chemical shift Q, as measured vis-à-vis a carrier offset centered at Ω_{ref}, are under the action of a gradient Gₑ, endows different positions with a quadratic phase given by the following equation (assuming ΔO·Tₑ>>1, negligible relaxation, and a small tip angle approximation):

$${φ}_{exc}^{chirp} ( z ) = γ {G}_{e} \frac{{T}_{e}}{2} ( z - {z}_{c} ) - \frac{1}{2} Δ {{OT}_{e} ( \frac{z - {z}_{c}}{L} )}^{2} - {T}_{e} Ω ( \frac{z - {z}_{c}}{L} ) + {φ}_{exc}^{{0}^{′}} \qquad ( 13 )$$

where

$$L = \frac{Δ O}{γ {G}_{e}}$$

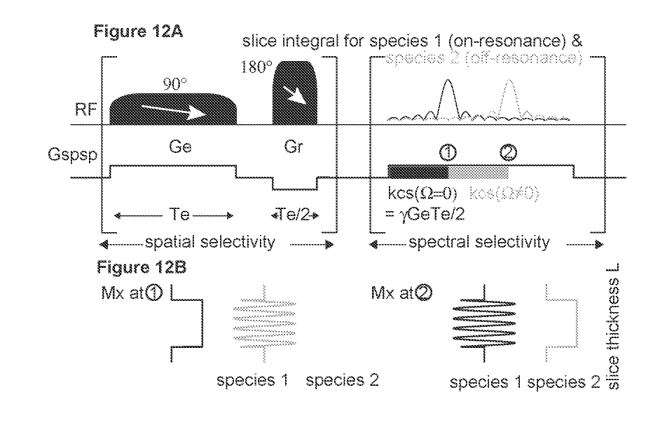

is the length of the excited region and zₑ the slice center for the on-resonance species. Of note is that this equation is equivalent to Eq. 2 wherein the parameters have been adapted for the analysis of SPSP selectivity. The last term in Eq. 13 is a constant and is disregarded henceforth. In SPEN magnetic resonance spectroscopy, an evolution phase that is proportional to both the spins' chemical shift and to their spatial coordinate is sought: φₑᵥₒₗ(z)=CΩ(z−zₑ), where C is a spatiotemporal constant under the experimentalist's control. The quadratic phase in Eq. 13 can be removed by applying a suitable, additional frequency-swept pulse. Exemplary pulses are described in e.g. Shrot et al., J. Chem. Phys. 128 (2008) 052209; and Pelupessy, J. Am. Chem. Soc. 125 (2003) 12345-12350. In one embodiment, a 180° pulse, sweeping the same region addressed by the excitation but in half the time; i.e., Tᵣ=Tₑ/2 is used. With this configuration, the first and second frequency-swept pulses can be used as the slice-selective excitation and refocusing pulses of a spin-echo imaging experiment, respectively. When gradients of equal signs and equal senses of sweep are used for excitation and refocusing, i.e., Gₑ=Gᵣ, a full and simultaneous rephasing of all terms is obtained regardless of chemical shifts. This option has been used for spin-echo imaging with several families of frequency-swept pulses (Balchandani et al., Magn. Reson. Med. 67 (2012) 1077-1085; Kunz, Magn. Reson. Med. 4 (1987) 129-136; and Park et al., Magn. Reson. Med. 61 (2009) 175-187). Alternatively, the sweeps can be kept equally signed but with a bipolar gradient Gᵣ=−Gₑ being applied. FIGS. 12A-12B illustrate a non-limiting example for obtaining simultaneous chemical shift and slice selection using a pair of frequency-swept pulses with opposite gradients. In particular, following the spatial excitation, a rephasing gradient of area k_{CS(Ω=0)=}γGₑTₑ/2 leads to rephasing of the on-resonance species across the slice. By utilizing a through-slice dephasing, the contribution of off-resonance species to the signal is cancelled. An additional gradient lobe k_{cs} (gray line) can be used to put an off-resonance species back in phase. The RF amplitude was set constant thus leading to a square-like pattern. By using amplitude modulation of the first pulse as is known to those of skill in the art, other profiles can be obtained.

When the sweeps are kept equally signed while using a bipolar gradient with Gᵣ=−Gₑ, the quadratic term in Eq. 13 vanishes but a site-dependent linear chemical shift term of the kind being sought remains (Park et al., Magn. Reson. Med. 61 (2009) 175-187; Shrot et al., J. Magn. Reson. 171 (2004) 163-170; Andersen et al., Magn. Reson. Chem. 43 (2005) 795-797; and Tal et al., J. Magn. Reson. 176 (2005) 107-114). FIG. 12B illustrates the spatial characteristics that arise for two sites with different chemical shifts. The spatial characteristics of the excited slice is given by the initial Oᵢ and final O_{f} frequencies, as well as by the profile of the B₁⁺(t) excitation RF pulse. As for the chemical shift effects, this pulse combination leads to a phase:

$${φ}_{CS} ( z ) = 2 {T}_{e} Ω \frac{z - {z}_{c}}{L} . \qquad ( 14 )$$

Given the z-linearity in this equation, a generic Ω leads to a null overall signal arising from the chosen slice. A suitable post-inversion k_{cs}, however, can bring any particular chemical site into a constructive superposition throughout the slice, thus leading to a site-specific observable signal. This is the principle used by SPEN for the ultrafast acquisition of indirect-domain spectra (Frydman et al., Proc. Natl. Acad. Sci. 99 (2002) 15858-15862, the contents of which are hereby incorporated in their entirety). Thus, an appropriate choice of the pulse duration Tₑ enables the refocusing which consequently enables visualization of one chosen species in the targeted slice, while dephasing the signals of all remaining off-resonance species excited in the region L.

The site-specific response arising from this scheme, assuming for simplicity a uniform spin density p across the excited slice L, is given by:

$$I ( Ω ) ∝ \frac{1}{L} {\int }_{- ( L - δ ) / 2}^{( L - δ ) / 2} p ( {z}^{′} ) exp ( 2 i Ω Te \frac{{z}^{′}}{L} ) d {z}^{′} {\approx }_{ρ \approx 1} \frac{sin [ Ω Te ( 1 - \frac{δ}{L} ) ]}{Ω Te} \qquad ( 15 )$$

where

$$δ = \frac{2 Ω}{γ {G}_{e}}$$

is a change in slice thickness brought about by the targeted chemical shift offset. For an off-resonance species, the chemical shift introduces opposite-signed displacements during the excitation and refocusing processes. Only the fraction of the slice that undergoes both pulses contributes to the signal; the remaining spins excited/inverted in the slice remain longitudinal or are suppressed by crusher gradients. For typical gradient and shift values, this loss is minor For multi-slice acquisitions, the existence of this slice displacement does not influence the inter-slice spacing that can be achieved; in particular, contiguous slices can be used and the full slice width (δ=0) can always be achieved for the on-resonance species.

Accordingly, SPEN-based pulse pair introduces a sinc-like selectivity vis-a-vis offset. For a given pair of sites located a (known) ΔΩ shift separation apart, a zero of this function (Eq. 15) can be set by choosing a sweep of duration

$${T}_{e} = p \frac{π}{Δ Ω} {( 1 - \frac{2 Δ Ω}{γ GeL} )}^{- 1} , \qquad ( 16 )$$

thus obtaining optimal suppression. p in this equation is an integer which can be adjusted to accommodate a maximum RF amplitude that is within hardware limitations for the desired bandwidth. According to Fourier principles, Eq. 16 sets the minimum separation between the selected and suppressed resonances to be inversely proportional to the duration used for the chirp-driven SPEN encoding (for p=1). In contrast to conventional 2D SPSP pulses, this is the time-scale available for achieving selectivity along the spatial dimension. This time is ca. an order of magnitude longer than what is usually available in the 2D SPSP pulses, boding well in terms of slice selectivity and spatial shaping.

Thus, according to the principles of the present invention, provided herein is a method of producing simultaneous spatial and spectral selectivity in magnetic resonance imaging. The method of the present invention obviates the need for fast oscillating gradients therefore providing a high-definition spatial profile without compromising on the spectral selectivity. Due to the relatively long irradiation periods used for imparting the spatial manipulations, improved slice profiling (and improved spatial sculpting) is provided. The method of the present invention can be utilized for detecting a single chemical species (e.g., water or fat) in a particular region of interest within an object. The method can, for example, be utilized for fat suppression in both single-shot or multi-shot excitations/acquisitions. Typical applications for fat suppression according to the principles of the present invention include, but are not limited to, diffusion tensor imaging (DTI, e.g. for mapping the connectivity in the brain) and functional magnetic resonance imaging (fMRI, Stenger et at, Magn. Reson. Med. 44 (2000) 525-531). Each possibility represents a separate embodiment of the present invention. In other embodiments, the concurrent collection of water and fat images can be obtained.

Within the scope of the present invention is the use of the method of the present invention for fast spectroscopic imaging, for example spectroscopic imaging of hyperpolarized metabolites. Accordingly, the present invention provides a method for spectroscopic imaging of biomarkers of interest which can be applied in e.g. preclinical applications of hyperpolarized ¹³C magnetic resonance. The method of the present invention can be implemented using existing clinical and pre-clinical MRI scanners. The method is compatible with multiple transmit/receive coils for parallel excitation/acquisition. Additional applications in which the method of the present invention can be implemented are magnetic resonance angiography, multidimensional NMR spectroscopy (for example, by selectively exciting or inverting multiple spectral dimensions such as, but not limited to, ¹H/¹³C and ¹H/¹⁵N/¹³C and to simultaneously select a region in phase and suppress the contribution from moving spins.

It will be appreciated by those of skill in the art that the acquired signal is typically transferred to a computer in order to perform post-acquisition processing as is known in the art. Common processing procedures include, but are not limited to, Fourier transformation, zero-filling, weighting, echo alignment procedures, magnitude calculations, resampling, algebraic reconstruction which can be iterative or non-iterative, and combinations thereof. Each possibility represents a separate embodiment of the present invention. Magnetic resonance images or spectra can then be displayed or stored in a storage medium.

Within the scope of the present invention is the use of any general purpose computer or computer system including a set of computer nodes and/or group members. Typical computer systems include at least a processor that is connected to a main memory, mass storage interface, terminal interface and network interface as described in e.g. WO 2007/078821, the contents of which are hereby incorporated in their entirety. Embodiments of the present invention incorporate interfaces that include separate, fully programmed microprocessors that are used to off-load processing from the CPU. Terminal interface is used to directly connect one or more terminals to the computer system. A network interface can be used to connect other computer systems or group members, to the computer system as is known in the art.

In general, the routines executed to implement the embodiments of the present invention, whether implemented as part of an operating system or a specific application, component, program, module, object or sequence of instructions may be referred to herein as a “program”. The computer program typically is comprised of a multitude of instructions that are translated by the computer into a machine-readable format and hence executable instructions. Also, programs are comprised of variables and data structures that either reside locally to the program or are found in memory or on storage devices. In addition, various programs described herein may be identified based upon the application for which they are implemented in a specific embodiment of the invention. However, it should be appreciated that any particular program nomenclature is used merely for convenience, and thus the invention should not be limited to use solely in any specific application identified and/or implied by such nomenclature.

It is also clear that given the typically endless number of manners in which computer programs may be organized into routines, procedures, methods, modules, objects, and the like, as well as the various manners in which program functionality may be allocated among various software layers that are resident within a typical computer (e.g., operating systems, libraries, API's, applications, applets, etc.) it should be appreciated that the invention is not limited to the specific organization and allocation or program functionality described herein. The present invention can be realized in hardware, software, or a combination thereof using one computer system or several interconnected computer systems. Any kind of computer system, or other apparatus adapted for performing the methods described herein, is suited.

According to certain aspects and embodiments, the present invention further provides a system for magnetic resonance imaging or spectroscopy comprising means for performing the method disclosed herein. Typical non-limiting means for performing the method disclosed herein include a radiofrequency transmitter suitable for applying a sweeping frequency irradiation in the form of a phase modulated and amplitude modulated RF pulse, at least one magnetic field gradient, and a collecting unit suitable for acquiring a magnetic resonance signal. Typically, the system for magnetic resonance imaging or spectroscopy of the present invention is connected to a computer or computer system with a computer program that, when being loaded and executed, controls the system for magnetic resonance imaging or spectroscopy such that it performs the method described herein. Each computer system may include, inter alia, one or more computers and at least a signal bearing medium allowing a computer to read data, instructions, messages or message packets, and other signal bearing information from the signal bearing medium. The signal bearing medium may include non-volatile memory, such as ROM, Flash memory, Disk drive memory, CD-ROM, and other permanent storage. Each possibility represents a separate embodiment of the present invention. Additionally, a computer medium may include, for example, volatile storage such as RAM, buffers, cache memory, and network circuits. Each possibility represents a separate embodiment of the present invention. Furthermore, the signal bearing medium may comprise signal bearing information in a transitory state medium such as a network link and/or a network interface, including a wired network or a wireless network, that allow a computer to read such signal bearing information.

An embodiment of the present invention can also be embedded in a computer program product, which comprises all the features enabling the implementation of the methods described herein, and which, when loaded in a computer system and conveyed to a system for magnetic resonance imaging or spectroscopy, provides the performance of the methods of the present invention. Computer program or products thereof in the present context means any expression, in any language, code or notation, of a set of instructions intended to cause a system having an information processing capability to perform a particular function such as, conversion to another language, code or, notation, and reproduction in a different material form. Thus, for example, computer programs or products thereof can be utilized to calculate the waveform of the RF pulses of the present invention which are then conveyed to the system for magnetic resonance imaging or spectroscopy to perform the method disclosed herein.

As used herein and in the appended claims the singular forms “a”, “an,” and “the” include plural references unless the content clearly dictates otherwise. Thus, for example, reference to “a frequency-swept irradiation” includes a plurality of such irradiations in a single or multiple dimensions and equivalents thereof known to those skilled in the art, and so forth Similarly, reference to “a magnetic field gradient” includes a plurality of such gradients and equivalents thereof known to those skilled in the art, and so forth. It should also be noted that the term “and” or the term “or” is generally employed in its sense including “and/or” unless the content clearly dictates otherwise.

The following examples are presented in order to more fully illustrate some embodiments of the invention. They should, in no way be construed, however, as limiting the broad scope of the invention. One skilled in the art can readily devise many variations and modifications of the principles disclosed herein without departing from the scope of the invention.

### EXAMPLES

Materials and Methods:

Spatial-Spatial Selectivity:

The data of the hybrid 2D pulse was collected at 7T on a Varian VNMRS 300/89 vertical-bore microimaging system (Varian associates, Palo Alto, Calif.) using a Millipede® probe. A water tube of 22 mm inner diameter was used as a phantom, on which either single-scan SPEN or multi-scan spin-echo images were obtained after applying a selective 2D excitation. The generation of all RF and gradient waveforms needed to perform these 2D pulse comparisons were written in Matlab® (The Mathworks, Natick, Mass.), and then exported into the NMR scanner where they were clocked out with 4 μs dwells. Data processing was also performed off-line using custom-written Matlab® routines. The pulses were compared with classic 2D k-space pulses as controls.

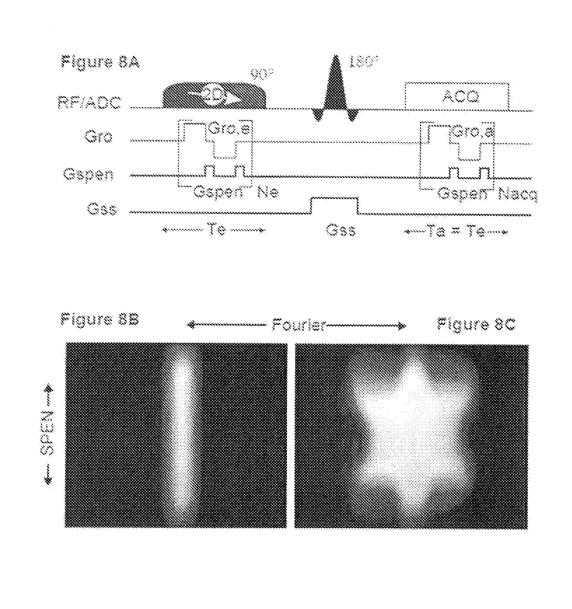

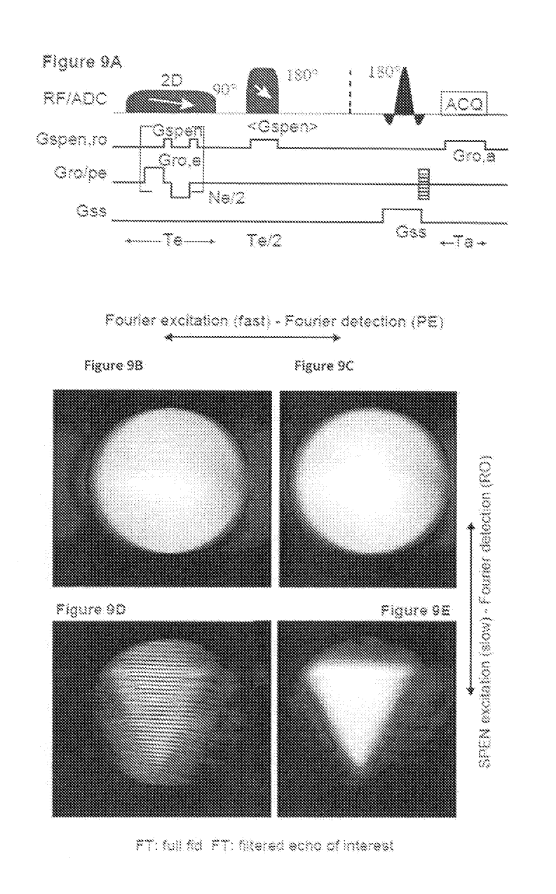

The experimental implementations that were tested employed the sequences shown in FIGS. 8A and 9A. A central refocusing 180° pulse was used to select a slice of 4 mm thickness, with phase-encoding and prephasing gradients played on both sides of this pulse, simultaneously with crusher gradients. During acquisition, the readout dimension was monitored with a 250 kHz bandwidth. To compare the performance of the classic k-space pulses with the hybrid 2D pulses, a flyback design was used, namely, RF was only played during odd k-lines (positive gradient of the zigzag). The flyback design allows avoiding timing imbalances which are most likely to occur due to eddy-currents that are not fully compensated on microimaging vertical hardware. Relaxation effects were not considered in the design of the RF waveforms.

Spatial-Spectral Selectivity:

2D RF pulses were designed using the SLR algorithm (Pauly et al., IEEE Trans. Med. Imag. 10 (1991) 53-65; WO 88/00699; and US 2010/0325185, the contents of each of which are hereby incorporated in their entirety) in order to achieve optimal spatial selectivity and signal intensity. Various modifications to the original SLR algorithm have been suggested to design non-linear-phase pulses of the kind demanded by SPEN-based sequences (Balchandani et al., Magn. Reson. Med. 64 (2010) 843-851; Schulte et al., J. Magn. Reson. 166 (2004) 111-122; and Shinnar, Magn. Reson. Med. 32 (1994) 658-660, the contents of each of which are hereby incorporated in their entirety). One such possibility comprises applying the desired non-linear phase to the SLR B-polynome in the frequency domain, prior to the inverse SLR transformation. Using this approach, a pulse can be designed that selectively excites the targeted band, with a phase:

$${φ}_{exc}^{SLR} ( z ) = γ {G}_{e} \frac{{T}_{e}}{2} ( z - {z}_{c} ) - \frac{1}{2} Δ {{OT}_{e}^{′} ( \frac{z - {z}_{c}}{L} )}^{2} + {φ}_{exc}^{0} , \qquad ( 17 )$$

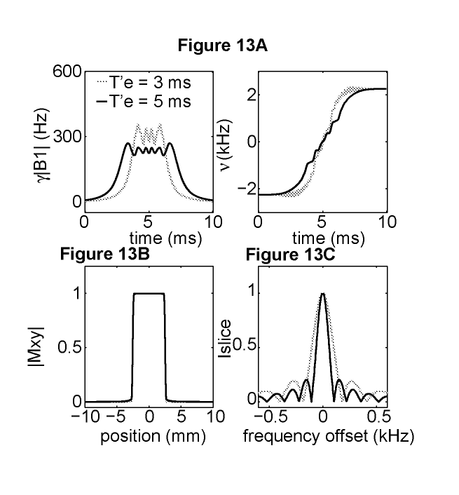

This is similar to Eq. 13 for an on-resonance species (i.e., with Ω=0), wherein the main difference involves a modification of the quadratic-phase coefficient given by a controllable T′ₑ. T′ₑ can be identified as the duration of the frequency sweep, which is slightly shorter than the total duration of the pulse, Tₑ. This difference between the sweeping duration and the pulse duration affords improving the high-frequency features associated with the desired spatial excitation profile; in particular, sharpening the transition regions of the slice-selective manipulations. FIGS. 13A-13B show non-limiting examples of the resulting quadratic-phase SLR excitation pulses. FIG. 13A demonstrates that approximately linear frequency sweep occupies a duration T′ₑ<Tₑ. FIG. 13B, 13C further provide numerical examples of the spatial and spectral selectivity profiles that can be obtained using the SLR approach. When dealing with off-resonance species, a chemical-shift dependent linear phase term arises. Accordingly, Eq. 17 has an additional chemical-shift winding term that is also T′ₑ -dependent:

$${φ}_{CS}^{SLR} = 2 {T}_{e}^{′} Ω \frac{z - {z}_{c}}{L} . \qquad ( 18 )$$

Refocusing pulses were also designed using the SLR algorithm. The condition required to remove the quadratic-phase imparted by the excitation is T′ᵣ=T′ₑ/2, provided that both pulses have the same bandwidth.

The general properties of frequency sweeps apply for quadratic-phase SLR pulses. For a given duration and bandwidth, these sweeps result in lowered maximum RF amplitudes, allowing the coverage of wider bands without exceeding maximum RF limitations. This, however, is achieved at the cost of an increased overall power deposition. Although specific parameter relations have not yet been fully derived for quadratic-phase SLR pulses, excellent selectivity can be obtained with simple choices of design parameters for the linear-phase filters. Demonstrated herein is a least-squares FIR filter with a time step of 8 μs, a fractional transition width of 0.2, and equal weights for the pass-band and stop-band characteristics.

Phantom Experiments:

The performance of the SPEN-based SPSP selectivity was assessed on phantom experiments performed at 7T using a Millipede® probe on a VNMRS 300/89 vertical-bore microimaging system (Varian Associates, Palo Alto, Calif.). The phantom contained two tubes of 11 mm ID, each filled with water and oil, respectively. The tubes were placed side-by-side. 2D spin-echo images were obtained after applying the SPEN strategy of FIGS. 12A-12B, with the SPEN spatial selectivity applied along either the slice-selective or the readout dimensions. When the SPEN-based pulses were used in the readout dimension, an additional (conventional) refocusing pulse was inserted between the second frequency-swept pulse and data acquisition for slice selection purposes. Phantom experiments were also performed at 3T on a Siemens Tim Trio clinical system (Siemens Healthcare, Erlangen, Germany) using a four-channel head coil. This phantom consisted of four water-containing spheres immersed in oil. 2D spin-echo images were obtained after a slice-selective SPEN-based pulse pair and compared against results obtained with a scanner-supplied SPAIR fat-suppressing sequence (Lauenstein et at, J. Magn. Reson. Imag. 27 (2008) 1448-1454), and against a custom-written extended two-point Dixon approach (Dixon, Radiol. 153 (1984) 189-194; and Skinner et al., Magn. Reson. Med. 37 (1997) 628-630).

Human Imaging Experiments:

The SPEN SPSP selectivity performance was further assayed by breast imaging studies on human volunteers. These experiments were performed at 3T on the Siemens Tim Trio clinical system using a four-channel breast coil, according to procedures approved by the Internal Review Board of the Wolfson Medical Center (Holon, Israel) and after obtaining suitable informed written consents of the volunteers. The SPEN-based excitation mode in FIGS. 12A-12B was implemented in three different imaging strategies. (i) water-only 2D multi-shot spin-echo images were collected after a slice-selective SPEN-based pulse pair, and compared against results obtained from a scanner-supplied sequence involving fat suppression; (ii) 2D single-shot spin-echo EPI images using a SPEN-based pulse pair were compared against reference images obtained using a Siemens-supplied 2D SPSP pulse for selective water excitation; (iii) concurrent water and fat images were collected following a pair of SPEN-based pulses, in a readout-interleaved fashion. This interleaving included the addition of suitable k_{cs} gradient lobes, effectively alternating back-and-forth among positions “1” and “2” in the spectral echoes of the water and fat resonances (FIGS. 12A-12B). These gradient pulses were applied along the slice-selection dimension, simultaneity with the phase-encoding blips of the EPI gradient waveform. Separate Fourier transformation of the odd and even EPI echoes thus yielded separated water and fat images, from a common slice-selected region.

All pulses were generated and all images were processed offline using suitable Matlab® scripts (The Mathworks, Natick, Mass.), available upon request. Pulses were designed and clocked out with 4 μs time-steps.

### Example 1

### Hybrid 2D Excitations and Single-Scan 2D SPEN Imaging

FIG. 8A shows the pulse sequence of a selective 2D excitation using a hybrid pulse and a SPEN-based detection. The 2D pulse had Nₑ=70 subpulses, a duration of Tₑ =30.8 ms and it was swept over ROI_{y}=20 mm with a time-bandwidth product Q=50 in the slow dimension. The waveform was obtained by FT of the targeted pattern along the fast dimension, and by adjusting the phase and amplitude of each subpulse according to that of a discretized chirp pulse. A readout gradient G_{RO}=10 kHz·mm⁻¹ was used during the subpulses. 70×70 points were acquired in a single scan in a total time of Tₐ=30.8 ms. ROIₓ was 2.5 cm in the readout dimension. Following suitable rearrangement, the signal was subjected to FT along the readout dimension (RO) and super-resolved along the SPEN dimension. The subpulses along the “fast” dimension were composed of identical sinc profiles and the ensuing excitation was monitored using single-scan 2D SPEN MRI. FIG. 8B shows a 2D image obtained using this pulse sequence. The intrinsic resolution of the images was enhanced by the use of a super-resolution algorithm as described in Ben-Eliezer et al., Magn. Reson. Med. 63 (2010) 1594-1600, and the acquisition was timed in order to record the full pseudo-echo in a fully refocused manner (Ben-Eliezer et al., Magn. Reson. Imaging 28 (2010) 77-86). The SPEN-based image does not require FT along the spatially encoded direction but only along the readout axis. The rectangular regions selectively excited by the sinc profiles are clear. Since the parameters were chosen such that the excitation sidebands fell outside the sample along the “slow” axis, only the center ROI was imaged.

It is therefore shown that hybrid 2D pulses can be used to provide slice selectivity to existing SPEN imaging sequences. In contrast to the method used in Ben-Eliezer et al., (NMR Biomed. 24 (2011) 1191-1201) which was based on using profiles that could be obtained by suitable intersection of two 1D selectively excited regions, the 2D hybrid SPEN pulse of the present invention can be used to excite complex shapes that are not the intersection of two 1D selectively excited regions. The ability of the 2D hybrid pulses of the present invention to excite such complex shapes is illustrated in FIG. 8C, which shows the excitation of a star-shaped region and its subsequent imaging with a single-scan SPEN sequence. By using a hybrid 2D pulse, the 2D Fourier transform of the region of interest was obviated in the design of the RF waveform. Instead, each subpulse was taken as a 1D Fourier transform of the corresponding line in the targeted region, and the frequency sweep along the “slow” dimension was then obtained by an overall phase modulation of the train of subpulses.

For a given excitation pattern and a given bandwidth, the power deposition for a SPEN-based and for a Fourier-based 2D pulse is comparable due to the fact that modulating a transverse magnetization with a quadratic-phase does not affect the energy required to excite it (Kunz, Magn. Reson. Med. 3 (1986) 377-384). Sequential excitation using a frequency-sweep, however, leads to a decrease of the maximum RF amplitude of a hybrid 2D pulse compared to a Fourier-based 2D pulse. Thus, SPEN-based 2D pulses have the same compatibility with the SAR requirements of in vivo imaging as conventional 2D pulses.

### Example 2

### Fourier Imaging Using Hybrid 2D Pulses Incorporating Quadratic Phase Refocusing

In order to demonstrate the use of the hybrid 2D pulses for conventional k-space imaging, a refocusing 180° chirp pulse was used to remove the quadratic phase imparted by these pulses. Apart from enabling conventional imaging, this adiabatic sweep opens the possibility to separate the contribution of the main ROI from that of undesirable excitation sidebands at an acquisition stage. This self-unfolding process is illustrated in FIGS. 9A-9E for both a discretized 1D chirp pulse exciting the full 22 mm diameter sample (FIG. 9B, 9C), and for a hybrid 2D pulse sculpting a triangle within this sample (FIG. 9D, 9E). The time-bandwidth product of these discretized chirp pulses was chosen to be ca. three times larger than the number of subpulses, and the RF intensities were adjusted to remain in the linear excitation regime of the pulses. In particular, the excitation chirp pulses were composed of Nₑ=100 (FIG. 9B, 9C) or 50 (FIG. 9D, 9E) subpulses, with a duration of Tₑ=20.4 ms, swept over a ROI=3 cm with a time-bandwidth product Q=200. A readout gradient G_{RO}=10 kHz·mm⁻¹ was used during these subpulses, and their amplitudes were chosen to operate in the linear regime. The excitation results were imaged by spin-echo MRI with 256×32 points and a field of view of 3×3 cm². The signal consisted of three well-separated echoes along the readout dimension, with each echo corresponding to a center/side-band. Images (FIG. 9B, 9D) were obtained by Fourier transforming the full signal in both dimensions after zero-filling to 256×128. Accordingly, an interfering sum of multiple folded bands along the “slow” dimension was obtained. In contrast, images (FIG. 9C, 9E) were obtained by filtering 100 and 50 points, respectively, wherein the points were centered on the echo and correspond to the targeted ROI, zero-filling to 128×128 points, and 2D FT. If only a selected echo is transformed along the lines described in FIGS. 3A-3E, undistorted images of the ROIs can be recovered (FIG. 9C, 9E). It is therefore shown that undistorted ROIs can be recovered despite the presence of strongly overlapping excitation sidebands.

FIGS. 10A-10C complements these demonstrations using spin-echo images of a non-uniform phantom, obtained after exciting it either with a non-selective pulse, a k-based 2D-selective excitation, or an analogous SPEN-/k-based hybrid pulse. The hybrid 2D pulse had a duration Tₑ=16.4 ms, Nₑ=32 subpulses and it was swept over a ROI=1.7 cm in the slow dimension with a time-bandwidth product Q=93. The Fourier 2D pulses had the same duration, number of subpulses, and ROI; the slow-dimension bandwidth was 4 times smaller than that of the hybrid 2D pulse. The bandwidth in the fast dimension was identical for both pulses and it was deduced from a readout gradient G_{RO}=10 kHz·mm⁻¹ The excitations were imaged by spin-echo MRI with 128×64 points and a field of view of 2.5×2.5 cm² Images (b, c) were obtained by filtering 50 points centered on the echo that corresponds to the targeted ROI, zero-filling to 128×128 points, and 2D FT. All three images clearly show the internal features of the ring-like structures of the phantom that was used. The main difference between the images afforded by conventional and SPEN-based 2D pulses arises from the higher robustness of the latter to field inhomogeneities. This confirms that SPEN-based forms of multidimensional excitation do not interfere with image quality for a given field of view and number of acquired points.

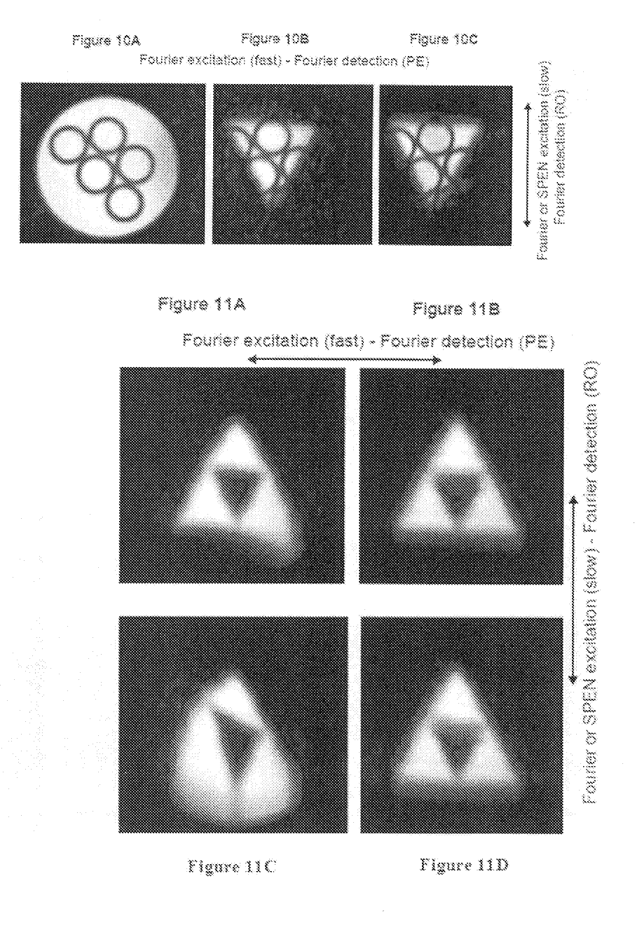

Although the unfolding/filtering procedure requires operating in a linear regime that may impose a price in terms of sensitivity, it also makes it possible to use more intense gradients in the “slow” dimension of a multidimensional pulse. FIGS. 11A-11D show that by enabling the pulse to operate under stronger gradient strengths, the sideband-unfolding approach can reduce the distortions that field inhomogeneities otherwise impart on excited ROIs. FIGS. 11A-11D compares the shaped patterns that were excited by conventional Fourier-based and by hybrid 2D pulses, wherein the pulses' total duration, number of intervening subpulses, and patterns/sizes of the ROI, were set equal. The gradient amplitudes used along the “slow” dimension, however, were set differently: for the Fourier case the gradient was set to Gₘₐₓ, i.e. to the maximum gradient strength that allows one to operate the pulse without any overlap between the ROI and the excitation sidebands (Eq. 4). For the hybrid 2D pulse, the gradient amplitude was set along this axis as 4*Gₘₐₓ, and the sideband-filtering approach was used to retrieve the signal elicited by the central ROI solely. In particular, the hybrid 2D pulse had a duration Tₑ=16.4 ms, Nₑ=32 subpulses and it was swept over a ROI=1.7 cm in the slow dimension with a time-bandwidth product Q=93. The Fourier 2D pulses had the same duration, number of subpulses, and ROI but the slow-dimension bandwidth was 4 times smaller than that of the hybrid 2D pulse. The bandwidth in the fast dimension was identical for both pulses and it was deduced from a readout gradient G_{RO}=10 kHz·mm⁻¹. Images were obtained using spin-echo MRI with 256×64 points and a field of view of 2.5×2.5 cm² by filtering 50 points centered on the echo that corresponds to the targeted ROI, zero-filling to 128×128 points, and 2D FT. As can be seen in FIGS. 11A-11D, the shapes excited by the k-space-based 2D pulse become highly distorted when an overall inhomogeneity of about 200 Hz is intentionally introduced (FIG. 11C). In contrast, the pattern excited by the hybrid 2D pulse shows a much more limited distortion (FIG. 11D). Thus, the pulses of the present invention provide an accurate and selective pattern-shaping in multiple dimensions in a single scan. Using the hitherto methods would require pulses on the order of 10 ms which are susceptible to distortions even under optimal shimming conditions. Thus, the pulses of the present invention provide a significant advantage over the prior art. Of note is that although the gradient amplitude is increased using this approach, the power deposition does not increase, because the overall excitation sculpting process still remains in the linear regime.

### Example 3

### Spectral-Spatial Selectivity using a Phantom at 7T

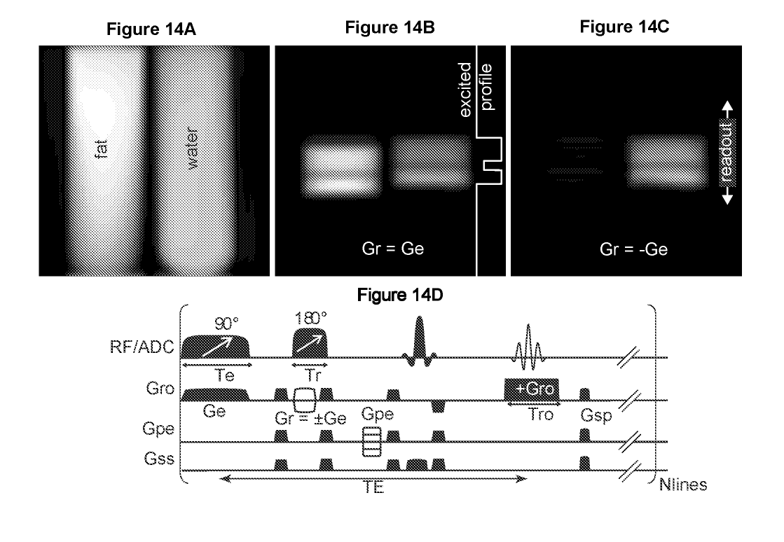

In order to assess the spatial and spectral selectivity of the SPEN-based approach, a simple water/fat phantom shown in FIG. 14A was used. The excitation pulse was obtained using the small-tip-angle approximation for a non-uniform shape of L=5 mm width. Pulses having a bandwidth of 10.5 kHz and a duration Tₑ=16 ms and Tᵣ=8 ms were used. The frequency sweeps had a T′ₑ=10 ms duration for excitation and T′ₑ/2 duration for refocusing. TE/TR=38/5000 ms. 128×64 points were acquired for a field of view of 2.5×2.5 cm²; 100×64 points centered around the water echo were filtered, zero-filled to 128×128, apodized with a Hamming window and Fourier transformed. 90°/180° frequency-swept pulses were applied along the readout axis. FIG. 14B shows the profile obtained upon using a sequence devoid from chemical-shift selectivity, which employed equal-gradient and equal-signed sweeps for excitation and refocusing. Further illustrated is the possibility to obtain a non-uniform intensity. The pulse scheme utilized Gₑ=Gᵣ as gradients for excitation and refocusing. The possibility to integrate a shift-selectivity into this scheme is illustrated in FIG. 14C. A pair of frequency-swept pulses was applied as shown in FIGS. 12A-12B, with Gₑ=−Gᵣ. The ensuing shift-dependent spatial winding (Eq. 14) results in the k_{cs}-shifts of the water and fat echoes. A water-only image can thus be obtained, by timing the readout echoing gradients so as to refocus solely this resonance while keeping the fat dephased.

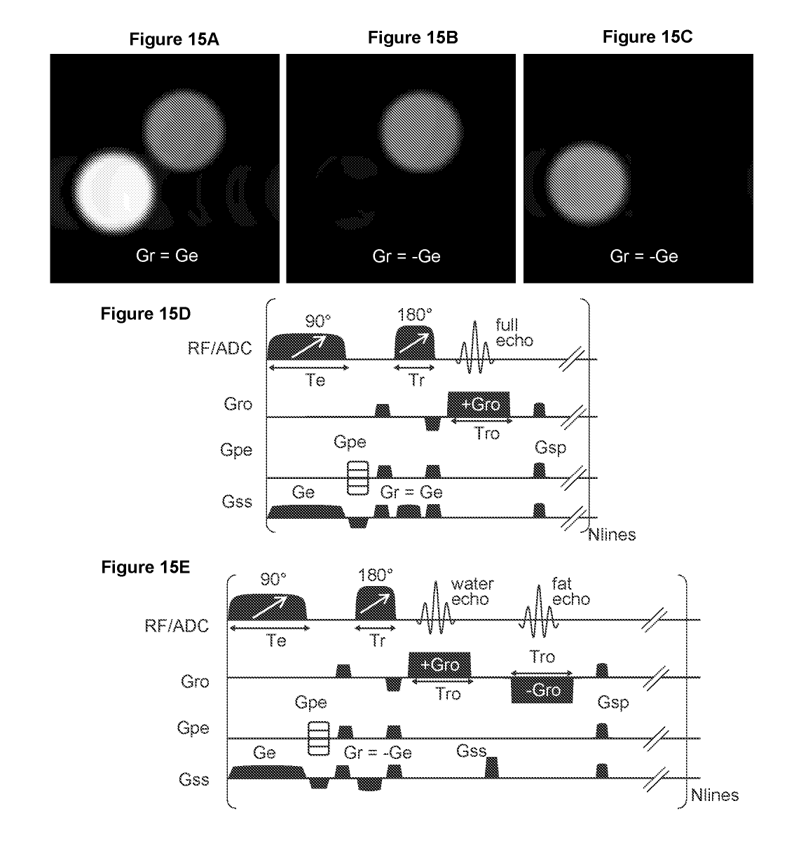

Hence, these pulses can provide a practical means to achieve chemical-shift specificity together with slice selectivity. This is further illustrated in FIGS. 15A-15E. The SLR pulses had a bandwidth of 10.5 kHz and a duration Tₑ=4.8 ms for excitation and Tᵣ=3.2 ms for refocusing, and the sweep durations were T′ₑ=3.0 ms for excitation and T′ₑ/2 for refocusing. The slice thickness was L=5 mm in all panels and 64×64 points were acquired with a field of view of 2.5×2.5 cm² and TE(water)/TE(fat)/TR=14/16/1000 ms. The data was zero-filled to 128×128 and apodized with a Hamming window before Fourier transformation. Whereas the Gₑ=Gᵣ condition in FIG. 15A leads to no shift selectivity, the residual fat signal remaining upon selectively choosing the water chemical shift focus FIG. 15B is less than 2% of its original value. Moreover, as fat is coherently dephased within the well-defined excited slice, a suitable k_{cs} gradient lobe in the slice-selection dimension can be used to rephase it while simultaneously dephasing the water. A fat echo can thus be acquired immediately following the acquisition of the water echo, as shown in FIG. 15C. The drop in the latter's signal intensity compared to a standard slice-selective spin-echo excitation is 50%. Without being bound by any theory or mechanism of action, this drop in signal intensity can be explained by the reduced slice thickness associated with the off-resonant effects, in addition to a small T₂*weighting related to the 2 ms delay between the water and the fat echoes in the concurrent acquisition.

### Example 4

### Spectral-Spatial Selectivity using a Phantom at 3T

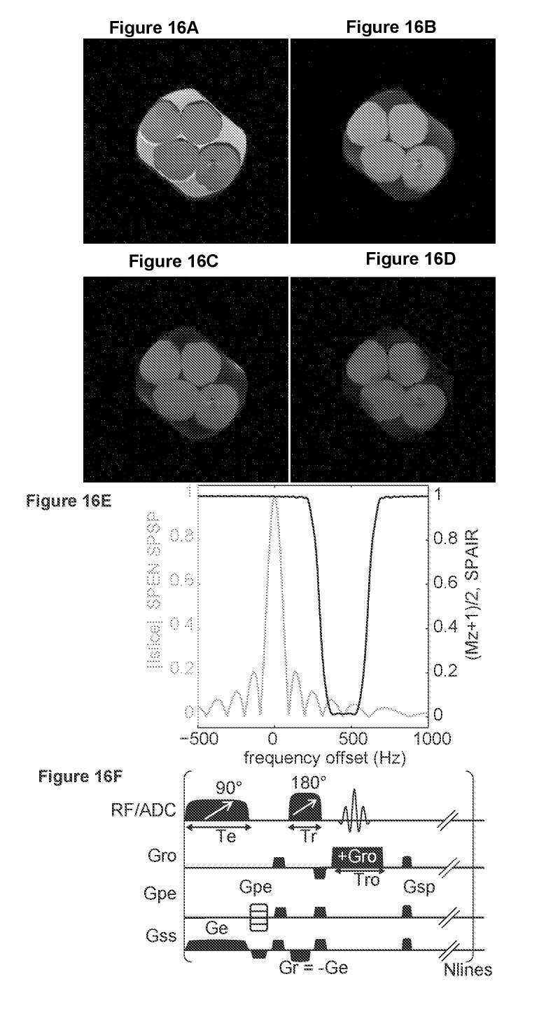

Further insight into the mechanism and performance of the SPEN SPSP approach was obtained by comparing the images obtained using the method of the present invention against alternatives obtained with canonical fat-suppression sequences. FIGS. 16A-16F shows a comparison against two well-established techniques, SPAIR and the extended two-point Dixon method, together with a non-fat-suppressed image. The slice thickness was L=6 mm and 256×205 points were acquired with a field of view of 18×18 cm². TE/TR=24/1000 ms. For the extended two-point Dixon method TE=49.2 ms for the second echo, which was acquired in the same shot after a refocusing pulse. The SPEN-based sequence, shown in FIG. 16F, relied on SLR pulses with 4.5 kHz bandwidths, a Tₑ=9.6 ms duration for excitation and Tᵣ=6 ms for refocusing, and sweep durations of T′ₑ=5.6 ms for excitation and T′ₑ/2 for refocusing. The distinct consequences of field inhomogeneities can be readily appreciated from this figure. In particular, the Dixon-based method (FIG. 16B) is shown to be the least sensitive to inhomogeneities but is also shown to be less spectrally selective. The difference between SPAIR (FIG. 16C) and SPEN SPSP (FIG. 16D) arises from the spectral selectivity profile shown in FIG. 16E, which illustrates that the former achieves a selective fat suppression while the latter achieves a selective water excitation. Among all these techniques, only the SPEN-based SPSP approach provides spectral selectivity and spatial localization simultaneously.

### Example 5

### Spectral-Spatial Selectivity with Human Volunteers at 3T

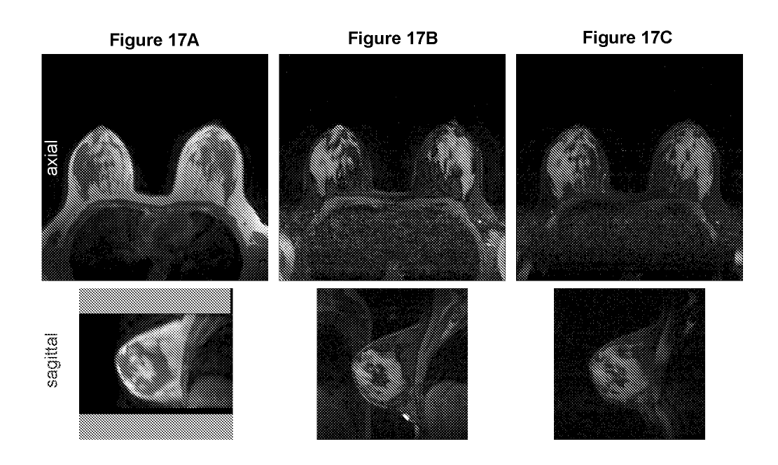

In order to explore the use of the 2D selective pulses in vivo, the method of the present invention was assayed at 3T with a series of breast imaging scans on female volunteers. Breast tissue is characterized by a small chemical-shift difference between the sites (≈450 Hz), as well as by large heterogeneities. FIGS. 17A-17C compare both axial and sagittal imaging arising from two different multi-scan sequences: spin-echo images collected using scanner-supplied SPAIR pulses (FIG. 17B), and spin-echo images arising upon performing SPEN-based SPSP pulses refocusing the water but not the fat resonances (FIG. 17C). A conventional gradient-echo image is also shown in FIG. 17A to illustrate the water/fat contrast according to the natural T₁ differences related to the anatomy of connective and fatty tissues. The slice thickness in FIG. 17B, c is L=5.5 mm and 256×128 points were acquired with a field of view of 33×33 cm² for the axial images and 24×24 cm² for the sagittal images. TE/TR=24/400 ms. For the SPEN-based SPSP selectivity, the pulses used are shown in FIG. 16F. The reference images with no fat suppression were obtained by volume rendering from an axial, multi-slice, Ti-weighted gradient-echo image. The slice thickness is 2.5 mm and 448×448 points were acquired with a field of view of 36×36×15 cm³; TE/TR=2.5/6.8 ms, flip angle=18°, and areas outside the acquired volume are shown in gray. Power deposition for five slices, as calculated by the scanner-supplied software, was 11% for the SPAIR sequence and 34% for the SPEN SPSP sequence. While using identical acquisition parameters which were employed for the two fat-suppression techniques, a cleaner separation of the connective tissues can be appreciated in the SPEN SPSP experiments (FIG. 17C). Moreover, sharper features are revealed upon using the SPSP pulses.

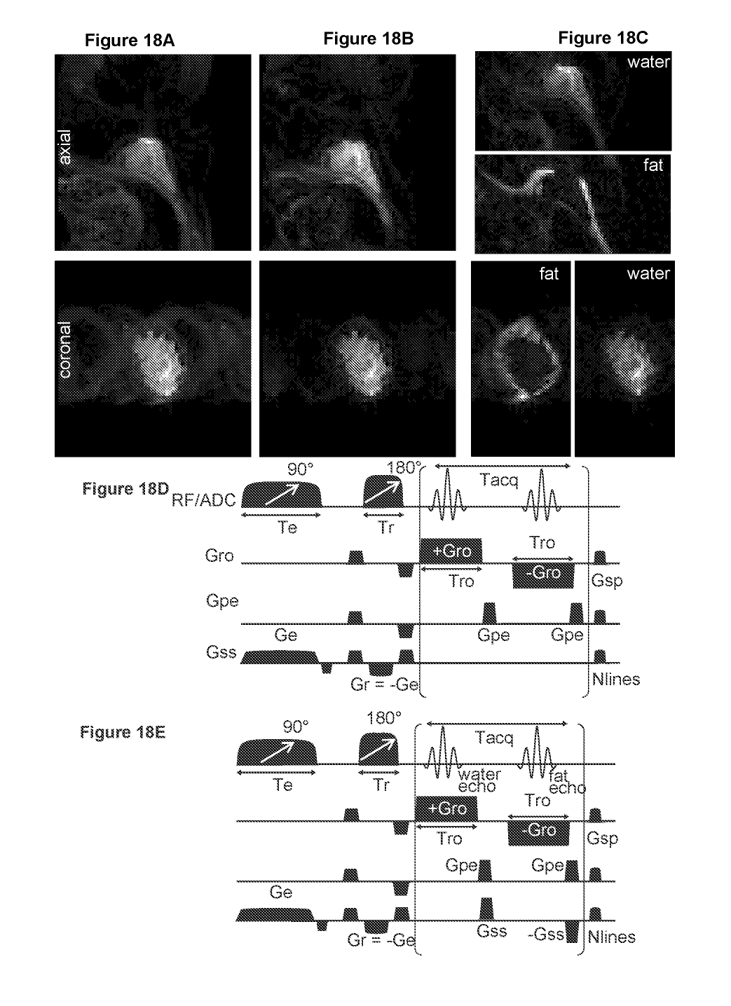

One of the main uses of 2D spectral-spatial selectivity centers on EPI acquisitions of multi-slice 2D water images. Given its relatively low bandwidth in the phase encoding direction, this single-shot technique usually requires an efficient suppression of fat signals that would otherwise lead to significantly shifted or blurred contributions. FIGS. 18A-18E illustrate the use of SPEN-based SPSP selectivity for fat suppression in multi-slice spin-echo EPI. The level of fat suppression observed using the SPEN-based SPSP pulses (FIG. 18B) was comparable, and even higher, with respect to the level of fat suppression that was achieved with selective water excitation using the scanner-supplied 2D SPSP pulses (FIG. 18A). The slice thickness is L=5 mm and 64×64 points were acquired with a field of view of 22×22 cm², and TE=44 ms Images were obtained in a single-shot (Nₗᵢₙₑₛ=64) with the minimum echo time achievable with the SPEN-based pulses. FIG. 18C illustrates another implementation of the SPEN scheme of the present invention, providing the simultaneous acquisition of water and fat images in a single shot. The two species (water and fat) are imaged simultaneously with water contributing only to the odd echoes and fat contributing to the even ones. The slice thickness is 10 mm and 64×32 points were acquired for each species with a field of view of 22×11 cm², and TE=72 ms. In these experiments, the field of view was made half along the phase-encoded dimension. Other choice of parameters, such as halving the resolution or doubling the acquisition time, is also possible. Thus, by using spatiotemporal encoding for spectral-spatial selectivity, superior fat suppression and increased spatial selectivity can be obtained.

Without being bound by any theory or mechanism of action, certain limitations stem from using the SPEN SPSP procedure due to the excitation of all species in the sample by the 90°/180° combination with the same flip angle. In addition, losses in the water signal as well as contaminations by the fat signal, particularly at lower field strengths may arise. Of note is that other offset-based methods such as SPAIR and conventional SPSP pulses share this limitation, while Dixon-based methods can show improved robustness against B₀ inhomogeneity. An additional mechanism that could influence the specific performance of frequency-swept SPSP pulses, including their effective SNR and contrast, concerns spin relaxation during the frequency-swept pulses, particularly transverse rotating frame relaxation (T_{2ρ}) over the course of the 90° excitation and 180° inversion. An additional diffusion weighting could arise, given the gradients and non-linear-phases introduced during the course of the pulse (Shrot et al., J. Chem. Phys. 128 (2008) 164513). Neither of these effects was detrimental in the present implementations due to the short durations of the frequency sweeps used.

### Example 6

### Fast Spectroscopic Imaging using a Phantom at 7T

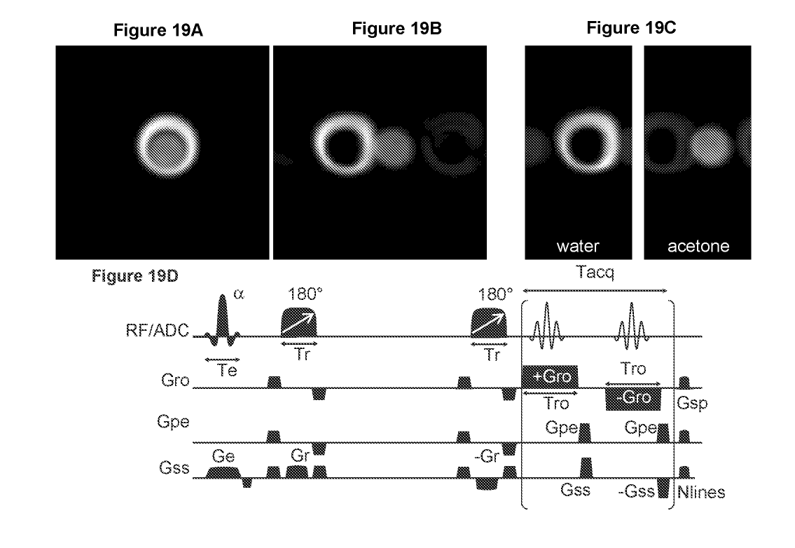

The performance of fast spectroscopic imaging using the method of the present invention was demonstrated. The SPEN-based spectral-spatial selectivity enables single-shot spectroscopic imaging, as illustrated in FIGS. 19A-19D. Experiments were performed on a microimaging system at 7 T with a phantom containing a tube filled with acetone inside a tube filled with water. FIG. 19A shows a reference multi-shot spin-echo image, acquired with a slice thickness of 4 mm, a FOV of 5×5 cm², a matrix size of 64×64, and TE/TR=8/1008 ms. FIG. 19b shows a reference single-shot spin-echo image, acquired with a slice thickness of 5 mm, a FOV of 5×5 cm², a matrix size of 64×64, and TE=44 ms. In these EPI experiments, both the acetone and the water contribute to the signal at all times and the two images cannot be separated. In addition, the significant chemical-shift difference between the two species leads to image distortion in the phase encoding dimension, as can be appreciated by comparing FIG. 19B with FIG. 19A. With the SPEN-based spectral-spatial selectivity, separate water and acetone images can be obtained in a single-shot, as illustrated in FIG. 19C, using the pulse sequence shown in FIG. 19D. The spectroscopic images in FIG. 19C were acquired with a slice thickness of 5 mm, a field of view of 5×2.5 cm, a matrix size of 64×32, and TE=44 ms. Quadratic-phase SLR refocusing pulses were used for spatiotemporal encoding. The pulses had a bandwidth of 10.5 kHz and 2.6 ms duration. For spectroscopic imaging, gradients of opposite sign were used during excitation and refocusing and additional gradients lobes were used in the slice-selection dimension during acquisition. The even and odd echoes of the blipped Cartesian trajectory were transformed separately to yield the water and acetone images. This sequence comprises a double spin echo for spatiotemporal encoding. This sequence can thus be used with a small-tip-angle excitation and a fast repetition rate, for example in hyperpolarized ¹³C spectroscopic imaging experiments.

### Example 7

### Localized Spectroscopy using a Phantom at 7T

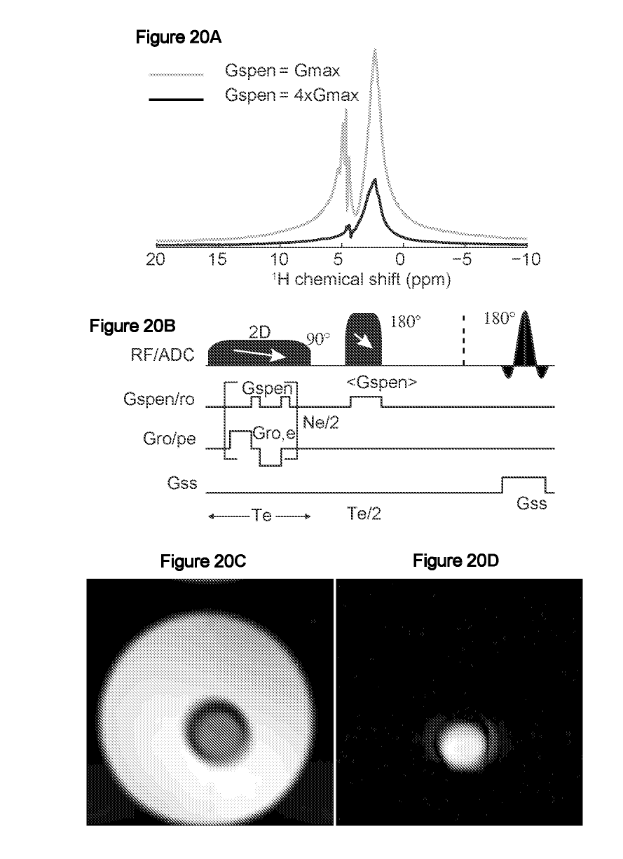

The performance of SPEN-based multidimensional pulses for localized spectroscopy in a non-cubic voxel was demonstrated. The higher bandwidth accessible with hybrid 2D pulses reduces contamination from chemicals outside the regions of interest, as illustrated in FIGS. 20A-20D. Experiments were performed on a microimaging system at 7T with a phantom containing a tube filled with acetone inside a tube filled with water. The spectrum in FIG. 20A was obtained by acquiring a free-induction signal (FID) after the localization module shown in FIG. 20B with a spectral width of 25 kHz and an acquisition time of 25 ms, zero-filling, apodizing and Fourier transforming In the localization module, a 2D pulse with a discretized frequency sweep in the slow dimension was used for excitation, with duration of 16.4 ms, and 64 subpulses. This pulse selects a circular region that corresponds to the acetone tube. A matched-phase refocusing pulse was used to remove the quadratic phase. A linear-phase refocusing pulse was used for selectivity in the third dimension.

Spatial selectivity can be assessed with the images shown in FIGS. 20C, 20D. The multi-shot spin-echo image in FIG. 20C was acquired with a slice thickness of 4 mm, a FOV of 2.5×2.5 cm², a matrix size of 64×64, and TE/TR=8/1008 ms. No in-slice selectivity was used in this reference image. The multi-shot spin-echo image in FIG. 20D was acquired with a slice thickness of 5 mm, a FOV of 2.5×2.5 cm², a matrix size of 128×128, and TE/TR=54/1055 ms, using the localization module shown in FIG. 20B.

With the maximum gradient value allowed for k-space-based 2D pulses in the low-bandwidth dimension, chemical-shift displacement of the voxel leads to water contamination of the localized spectrum. By using such gradient value, the region of interest does not overlap with the excitation sidebands in the slow dimension. With a higher gradient value allowed by the hybrid 2D pulse, water contamination is avoided, at the cost of a decreased sensitivity. In this case, self-unfolding is used to retrieve the signal that originates from the region of interest despite overlapping sidebands.

### Example 8

### 3D Spatial Selectivity using a Phantom at 7T

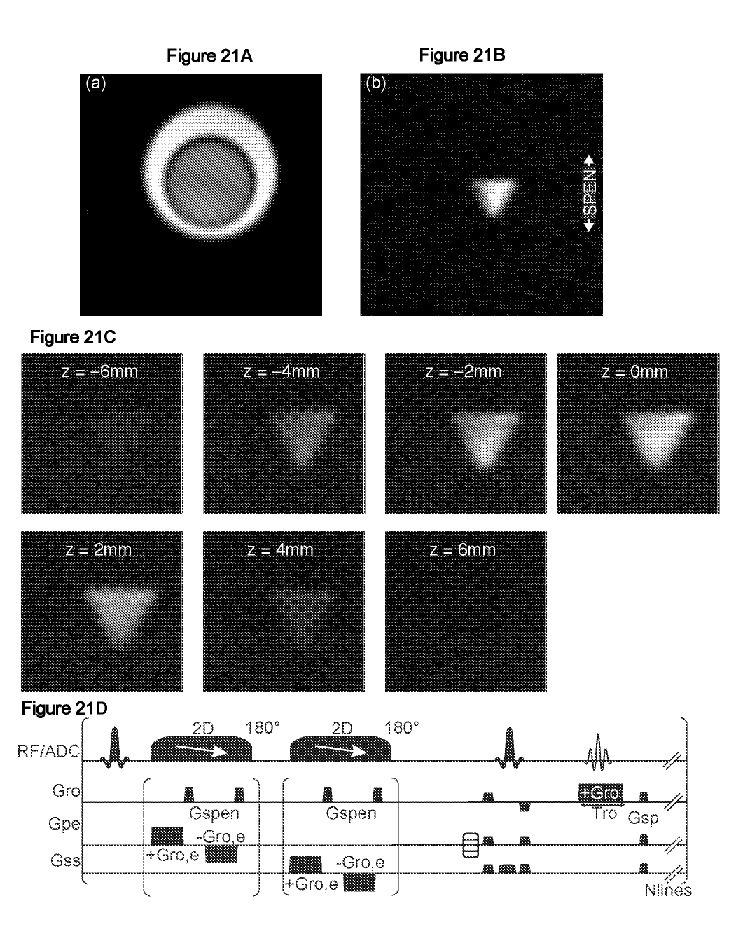

Three-dimensional spatial selectivity using a pair of 2D hybrid refocusing pulses was demonstrated. A complex 3D shape was sculpted with no interference from sidebands, using the method of the present invention. Experiments were performed on a microimaging system at 7 T, using a phantom containing a tube filled with acetone inside a tube filled with water. FIG. 21A shows a reference multi-shot spin-echo image, acquired with a slice thickness of 4 mm, a FOV of 2.5×2.5 cm², a matrix size of 64×64, and TE/TR=8/1008 ms. No in-slice selectivity was used in this reference image. FIG. 21B, c show multi-shot spin-echo images obtained with the sequence shown in FIG. 21D. The image in FIG. 21B was obtained with a slice thickness of 5 mm, a FOV of 2.5×2.5 cm², a matrix size of 256×64, and TE/TR=62/1063 ms. The images in FIG. 21C were obtained with a slice thickness of 5 mm, a reduced FOV of 1×1 cm², a matrix size of 128×32, and TE/TR=62/1063 ms. A spectrally selective pulse was used to selectively excite the acetone resonance. A triangle was selected in the xy plane and a square was selected in the yz plane, where x=PE, y=RO and z=SS. The hybrid 2D refocusing pulses had 24.6 ms duration and 64 subpulses for the first pulse and 96 for the second pulse. An average gradient of Gₘₐₓ=min(2πN_{r,1}/(γLₓTᵣ), 2πN_{r,2}/(γL_{X}Tᵣ)) was used in the slow dimension, where Nᵣ is the number of subpulses, Lx is the length of the region of interest and Tᵣ is the duration of the pulse. By using such gradient amplitude, sidebands are contiguous for the first pulse and separated by Lₓ/2 for the second pulse. As a result, there is a residual band-dependent linear phase for the sidebands located within the sample. Consequently, the sidebands do not contribute to the acquired signal. A larger bandwidth can thus be used, compared to a case where all sidebands have to be outside the sample. The last refocusing pulse selected a slice to obtain a multi-slice 2D image of the ROI. Similarly, 3D imaging could be used instead.

### Example 9

### 4D Spatial and Spectral Selectivity

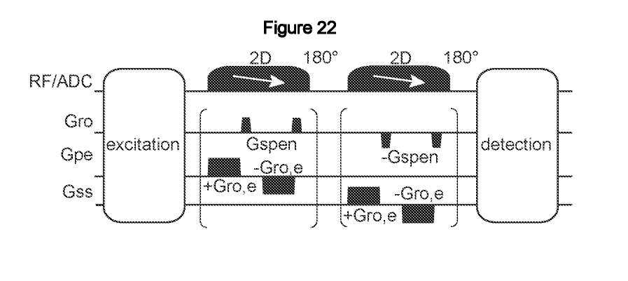

With the three-dimensional spatial selectivity achieved as demonstrated in Example 8, a few options arise that could enable an ultimate spatial-spatial-spatial-spectral selectivity of the method of the present invention. One of the options relies on using the initial excitation pulse shown in FIGS. 21A-21D for spectral selectivity. The ensuing spatial sculpting thus affects only a selected resonance, as all other peaks experience a net zero rotation after the action of the two 2D 180° pulses. Alternatively, given the facts that: i) a pair of 180° pulses can also deliver a spectrally selective winding together with spatial selectivity if executed as illustrated in FIGS. 19A-19D, and ii) the two 2D pulses in FIGS. 21A-21D encompass 180° swept inversions along their common Gspen axis (corresponding to Gro in FIG. 21D), a suitable gradient sign inversion as illustrated in FIG. 22, could lead to another option to select a particular spectral line. This leaves in turn the option of utilizing the initial excitation pulse in the sequence to achieve some other kind of selectivity—for instance a slab selection.

It is appreciated by persons skilled in the art that the present invention is not limited by what has been particularly shown and described hereinabove. Rather the scope of the present invention includes both combinations and sub-combinations of various features described hereinabove as well as variations and modifications. Therefore, the invention is not to be constructed as restricted to the particularly described embodiments, and the scope and concept of the invention will be more readily understood by references to the claims, which follow.

What is claimed is:

1. A method for producing multidimensional selectivity in magnetic resonance imaging or spectroscopy, the method comprising the steps of: (a) applying a magnetic field gradient being configured to partition a sample into a set of subensernbles endowed with different resonance frequencies while concurrently applying a frequency-swept irradiation to sequentially manipulate said subensembles in at least one dimension; (h) optionally applying at least one of an irradiation, a magnetic field gradient, or a combination thereof, being configured to remove undesired phase or aliasing imparted to the subensembles during step (a) or to further manipulate a desired subensemble; and acquiring a signal arising from said subensembles, thereby providing magnetic resonance imaging or spectroscopy with multidimensional selectivity.

2. The method of claim 1, wherein said multidimensional selectivity is in at least two dimensions selected from spatial dimension, spectral dimension, displacement-based dimension, relaxation-based. dimension, and combinations thereof.

3. The method of claim 1, wherein said multidimensional selectivity is a three-dimensional spatial-spatial-spectral selectivity.

4. The method of claim 1, wherein said multidimensional selectivity is a three-dimensional spatial-spatial--spatial selectivity.

5. The method of claim 1, wherein said multidimensional selectivity is a four-dimensional spatial-spatial-spatial-spectral selectivity.

6. The method of claim 1, wherein the frequency-swept irradiation is a substantially linearly frequency-swept irradiation.

7. The method of claim 1, wherein the frequency-swept irradiation is applied in a continuous manner.

8. The method of claim 1, wherein the frequency-swept irradiation is applied in a discretized manner.

9. The method of claim 1, wherein step (a) is performed using a discretized frequency-swept irradiation comprising a plurality of irradiation sub-pulses interleaved with a plurality of magnetic field gradients.

10. The method of claim 1, wherein the frequency-swept irradiation in step (a) induces at least one of excitation, crushing, inversion, refocusing and storage of the subensembles.

11. The method of claim 1, wherein step (a) further comprises concurrently applying at least one other magnetic field gradient to sequentially manipulate said subensembles along a predetermined multidimensional trajectory.

12. The method of claim 11 wherein step (a) comprises the use of two orthogonal magnetic field gradients to sequentially manipulate said subensembles along a predetermined two-dimensional trajectory.

13. The method of claim 12, wherein the two--dimensional trajectory is selected from a Cartesian trajectory, a spiral trajectory, and a radial trajectory.

14. The method of claim 1, wherein step (a) further comprises concurrently applying at least one other magnetic field gradient being configured to impart spatial selectivity within said subensembles using a predetermined k-space trajectory.

15. The method of claim 1. wherein the irradiation in step (h) is a frequency-swept irradiation.

16. The method of claim 1, wherein the irradiation in step (h) induces at least one of excitation, crushing, inversion, refocusing and storage of the subensembles.

17. The method of claim 1, wherein the magnetic field gradient in step (h) comprises at least one of a crusher magnetic field gradient, a refocusing magnetic field gradient, and a combination thereof.

18. The method of claim 1, wherein acquiring a signal step (c) comprises the use of at least one of gradient echo, spin echo, fast low angle shot (FLASH), fast spin echo (FSE), and echo planar imaging (EPI).

19. The method of claim 1, wherein the step of acquiring a signal in step (c) comprises the use of a time-dependent magnetic field gradient being configured to unravel the partition of the sample into a set of subensembles imparted during step (a).

20. The method of claim 1 which is performed in a single scan.

21. The method of claim 1 for multidimensional magnetic resonance imaging of objects being characterized by complex architectures.

22. The method of claim I for multidimensional magnetic resonance imaging of a region of interest within an object, wherein said region of interest is characterized by complex architectures.

23. The method of claim I for localized magnetic resonance spectroscopy in a predetermined region of interest within an object.

24. The method of claim 1 for producing multidimensional selectivity in magnetic resonance imaging or spectroscopy even in the presence of magnetic field distortions.

25. The method of claim 1 further comprising the, step of processing the acquired signal by using at least one of Fourier transformation, zero-filling, weighting, echo alignment procedures, magnitude calculations, resampling, algebraic reconstruction, and combinations thereof.

26. A system for magnetic resonance imaging or spectroscopy comprising means for performing the method of claim 1.

27. The system of claim 26, wherein said means for performing the method comprise at least one of a radiofrequency transmitter being configured to apply a frequency-swept irradiation, a magnetic field gradient being configured to partition a sample into a set of subensembles endowed with different resonance frequencies, and a collecting unit being configured to acquire a magnetic resonance signal.
